(19) United States
(12) Patent Application Publication
(10) Pub. No.: US 2026/0314027 A1
(43) Pub. Date: Oct. 8, 2026

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Kuei-Yu Kao, Hsinchu (TW); Chiung-Yu Cho, Hsinchu (TW); Poya Chuang, Hsinchu (TW); Yu-Shan Lu, Zhubei City (TW)

(73) Assignee: Taiwan Semiconductor Manufacturing Company, Ltd., Hsinchu (TW)

(21) Appl. No.: 19/169,652

(22) Filed: Apr. 3, 2025

(51) Int. Cl. H10D 84/01; H10D 30/00; H10D 30/01; H10D 30/43; H10D 62/10; H10D 62/13; H10D 64/01; H10D 64/27; H10D 84/83

(52) U.S. Cl. CPC H10D 84/0135; H10D 30/014; H10D 30/0191; H10D 30/503; H10D 30/506; H10D 64/017; H10D 64/516; H10D 64/518; H10D 30/43; H10D 62/121; H10D 62/151; H10D 84/832

(57) ABSTRACT

A method, includes: providing a semiconductor structure including a plurality of vertically spaced channel structures, a plurality of vertically spaced interlayer oxide regions positioned between the plurality of vertically spaced channel structures, a sacrificial gate structure disposed above the plurality of vertically spaced channel structures, a source feature, and a drain feature; removing the sacrificial gate structure via dry etching operations; removing interlayer oxide above a top channel structure of the plurality of vertically spaced channel structures via dry etching operations; and removing remaining portions of the plurality of vertically spaced interlayer oxide regions via chemical etching operations.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum feature sizes are reduced, additional problems arise that should be addressed.

### BRIEF DESCRIPTION OF DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow chart depicting an example method of semiconductor fabrication including fabrication of multi-gate devices, in accordance with some embodiments.

FIGS. 2-3, 4A-4C, 5, 6A-6B, and 7-18, are schematic diagrams illustrating an example semiconductor device or structure at various stages of fabrication, in accordance with some embodiments.

FIGS. 19-22 are schematic diagrams illustrating an example semiconductor structure that has undergone a process for removing sacrificial oxide layers and releasing the nanosheets during fabrication of a GAA device, in accordance with some embodiments.

FIGS. 23-26 are schematic diagrams illustrating various features of an example semiconductor structure after removal of the sacrificial oxide layer from between the channel layers, in accordance with some embodiments.

FIGS. 27-28 are schematic diagrams illustrating various features of an example semiconductor structure after subsequent metal gate fabrication operations, in accordance with some embodiments.

FIGS. 29-30 are schematic diagrams illustrating various features of an example short-channel semiconductor structure after removal of the sacrificial oxide layer from between the channel layers, in accordance with some embodiments.

FIGS. 31-32 are schematic diagrams illustrating various features of an example long-channel semiconductor structure after removal of the sacrificial oxide layer from between the channel layers, in accordance with some embodiments.

FIGS. 33-34 are schematic diagrams illustrating another example semiconductor structure after subsequent metal gate fabrication operations, in accordance with some embodiments.

FIG. 35 is a flow chart depicting an example method of semiconductor fabrication including fabrication of multi-gate devices, in accordance with some embodiments.

FIGS. 36-38 are schematic diagrams illustrating a semiconductor device at various stages of fabrication, in accordance with some embodiments.

FIG. 39 is a process flow chart illustrating an example etching sequence, in accordance with some embodiments.

FIGS. 40 and 41 are cross-sectional schematic views of a semiconductor structure depicting a plurality of dummy gate structures disposed over an epitaxial stack, in accordance with some embodiments.

FIG. 42 is a cross-section schematic diagram illustrating example kink characteristics of dummy gates on a semiconductor structure, in accordance with some embodiments.

FIG. 43 is a diagram depicting an example formula for determining a kink ratio, in accordance with some embodiments.

FIG. 44 is a diagram depicting example calculations made using the formula of FIG. 43, in accordance with some embodiments.

FIG. 45 is a cross-sectional schematic diagram depicting an example metal gate structure that has been formed after a bias reduction sequence was used during dummy gate patterning operations, in accordance with some embodiments.

FIGS. 46 and 47 are schematic cross-sectional views depicting an example metal gate structure that has been formed after a bias reduction sequence was used during dummy gate patterning operations, in accordance with some embodiments.

FIGS. 48 and 49 illustrate another example semiconductor structure after metal gate fabrication operations when a bias reduction sequence was used during dummy gate patterning operations, in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting.

For the sake of brevity, conventional techniques related to conventional semiconductor device fabrication may not be described in detail herein. Moreover, the various tasks and processes described herein may be incorporated into a more comprehensive procedure or process having additional functionality not described in detail herein. In particular, various processes in the fabrication of semiconductor devices are well-known and so, in the interest of brevity, many conventional processes will only be mentioned briefly herein or will be omitted entirely without providing the well-known process details. As will be readily apparent to those skilled in the art upon a complete reading of the disclosure, the structures disclosed herein may be employed with a variety of technologies, and may be incorporated into a variety of semiconductor devices and products. Further, it is noted that semiconductor device structures include a varying number of components and that single components shown in the illustrations may be representative of multiple components.

It should be understood that, although the terms first, second, third etc. may be used herein to describe various elements, components, regions, layers, portions and/or sections, these elements, components, regions, layers, portions, and/or sections should not be limited by these terms. These terms are only used to distinguish one element, component, region, layer, portion or section from another region, layer, or section. Thus, a first element, component, region, layer, portion, or section discussed below could be termed a second element, component, region, layer, portion, or section without departing from the teachings of the present disclosure.

Furthermore, spatially relative terms, such as “over”, “overlying”, “above”, “upper”, “top”, “under”, “underlying”, “below”, “lower”, “bottom”, and the like, may be used herein for ease of description to describe one element's or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. When a spatially relative term, such as those listed above, is used to describe a first element with respect to a second element, the first element may be directly on the other element, or intervening elements or layers may be present.

In addition, the present disclosure may repeat reference numerals and/or letters in the various examples. This repetition is for the purpose of simplicity and clarity and does not in itself dictate a relationship between the various embodiments and/or configurations discussed.

It is noted that references in the specification to “one embodiment,” “an embodiment,” “an example embodiment,” “exemplary,” “example,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to affect such feature, structure, or characteristic in connection with other embodiments whether or not explicitly described.

In certain embodiments herein, a “material layer” is a layer that includes at least 50 wt. % of the identified material, for example at least 60 wt. % of the identified material, at least 75 wt. % of the identified material, at least 90 wt. % of the identified material, at least 95 wt. % of the identified material, or at least 99 wt. % of the identified material; and a layer that is a “material” includes at least 50 wt. % of the identified material, for example at least 60 wt. % of the identified material, at least 75 wt. % of the identified material, at least 90 wt. % of the identified material, at least 95 wt. % of the identified material, or at least 99 wt. % of the identified material. For example, certain embodiments, each of an aluminum layer and a layer of aluminum is a layer that is at least 50 wt. %, at least 60 wt. %, at least 75 wt. %, at least 90 wt. %, at least 95 wt. %, or at least 99 wt. % of aluminum.

It is to be understood that the phraseology or terminology expressed herein is for the purpose of description and not of limitation, such that the terminology or phraseology of the present specification is to be interpreted by those skilled in relevant art(s) in light of the teachings herein.

The following disclosure provides many different embodiments, or examples, for implementing different features of the disclosed subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. Throughout the description herein, unless otherwise specified, the same reference numeral in different figures refers to the same or similar component formed by a same or similar method using a same or similar material(s).

While the figures illustrate various embodiments of a semiconductor device, additional features may be added in the semiconductor device depicted in the Figures and some of the features described below can be replaced, modified, or eliminated in other embodiments of the semiconductor device.

Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

As used herein, a “layer” is a region, such as an area comprising arbitrary boundaries, and does not necessarily comprise a uniform thickness. For example, a layer can be a region comprising at least some variation in thickness.

The present disclosure is generally related to semiconductor devices and the fabrication thereof, and in some cases to multi-gate devices. Multi-gate devices include those transistors whose gate structures are formed on at least two-sides of a channel region. These multi-gate devices may include an n-type metal-oxide-semiconductor device or a p-type metal-oxide-semiconductor multi-gate device. Specific examples herein may be presented and referred to herein as a type of multi-gate transistor referred to as a gate-all-around field effect transistor (GAAFET). A GAAFET includes any device that has its gate structure, or portion thereof, formed on 4-sides of a channel region (e.g., surrounding a portion of a channel region). Devices presented herein also include embodiments that have channel regions disposed in nanosheet channel(s), nanowire channel(s), bar-shaped channel(s), and/or other suitable channel configurations. Presented herein are embodiments of devices that may have one or more channel regions (e.g., nanosheets) associated with a single, contiguous gate structure. One of ordinary skill may recognize other examples of semiconductor devices that may benefit from aspects of the present disclosure.

During formation of various multi-gate devices (such as GAAFET, nanosheet FET (NSFET), Fork-sheet FET, complementary FET (CFET), vertical field effect transistor (VFET), and others), the metal gate (MG) bottom side contact area may be reduced which can induce drain induce barrier lowering (DIBL) degradation. Structures and techniques disclosed herein can increase a metal gate (MG) to Si channel contact area thereby reducing DIBL degradation.

During formation of various multi-gate devices, metal gate (MG) side wall kinking may occur, which can degrade manufacturing yield and device performance. Structures and techniques disclosed herein can reduce MG side wall kinking.

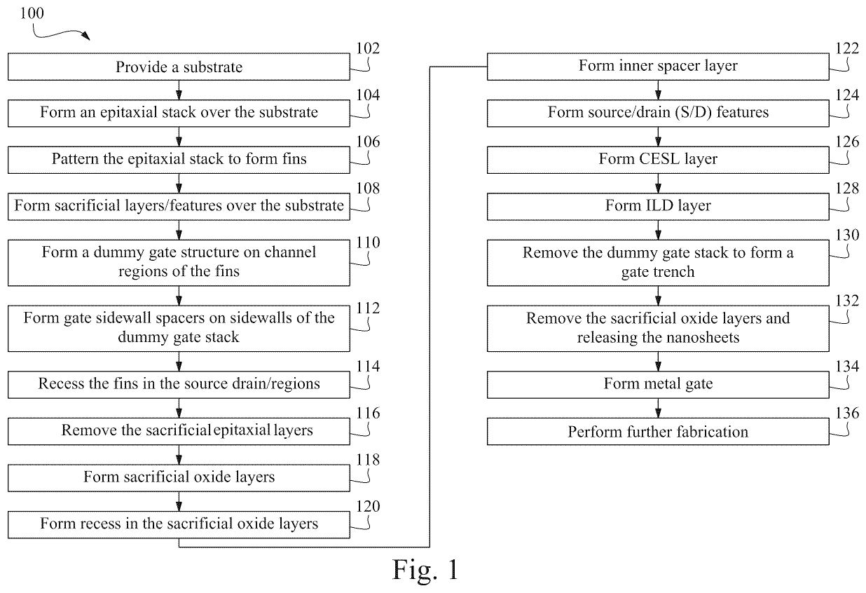

FIG. 1 is a flow chart depicting an example method 100 of semiconductor fabrication including fabrication of multi-gate devices, according to various aspects of the present disclosure. As used herein, the term “multi-gate device” is used to describe a device (e.g., a semiconductor transistor) that has at least some gate material disposed on multiple sides of at least one channel of the device. In some examples, the multi-gate device may be referred to as a GAA device having gate material disposed on four sides of at least one channel member of the device. The channel member may be referred to as “nano structure” or “nanosheet,” which is used herein to designate any material portion with nanoscale, or even microscale dimensions, and having an elongate shape, regardless of the cross-sectional shape of this portion. Thus, the term “nanostructure” or “nanosheet” as used herein designates both circular and substantially circular cross-section elongate material portions, and beam or bar-shaped material portions including for example a cylindrical in shape or substantially rectangular cross-section.

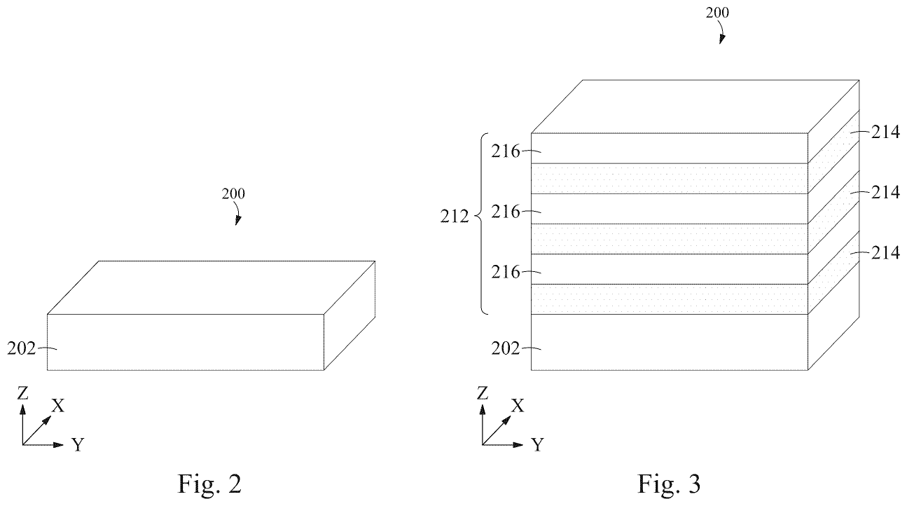

FIG. 1 is described in conjunction with FIGS. 2-3, 4A-4C, 5, 6A-6B, and 7-18, which illustrate a semiconductor structure 200 or structure at various stages of fabrication in accordance with some embodiments. In some figures, some reference numbers of components or features illustrated therein may be omitted to avoid obscuring other components or features; this is for ease of depicting the figures. The method 100 is merely an example and is not intended to limit the present disclosure beyond what is explicitly recited in the claims. Additional steps may be provided before, during, and after method 100, and some of the steps described can be moved, replaced, or eliminated for additional embodiments of method 100. Additional features may be added in the semiconductor structure 200 depicted in the figures, and some of the features described below can be replaced, modified, or eliminated in other embodiments.

As with the other method embodiments and exemplary devices discussed herein, it is understood that parts of the semiconductor devices may be fabricated by semiconductor technology process flow, and thus some processes are only briefly described herein. Further, the exemplary semiconductor devices may include various other devices and features, such as other types of devices such as additional transistors, bipolar junction transistors, resistors, capacitors, inductors, dials, fuses, and/or other logic devices, etc., but is simplified for better understanding of concepts of the present disclosure. In some embodiments, exemplary devices include a plurality of semiconductor devices (e.g., transistors), including PFETs, NFETs, etc., which may be interconnected. Moreover, it is noted that the process steps of method 100, include any descriptions given with reference to the figures, as with the remainder of the method and exemplary figures provided in this disclosure, are merely exemplary and are not intended to be limiting beyond what is specifically recited in the claims that follow.

At block 102, the example method 100 includes providing a substrate. Referring to the example of FIG. 2, in an embodiment of block 102, a substrate 202 is provided for forming a semiconductor structure 200. In some embodiments, the substrate 202 may be a semiconductor substrate such as a silicon (Si) substrate. In some embodiments, the substrate 202 includes a single crystalline semiconductor layer on at least its surface portion. The substrate 202 may comprise a single crystalline semiconductor material such as, but not limited to Si, Ge, SiGe, GaAs, InSb, GaP, GaSb, InAlAs, InGaAs, GaSbP, GaAsSb and InP. Alternatively, the substrate 202 may include a compound semiconductor and/or an alloy semiconductor. The substrate 202 may include various layers, including conductive or insulating layers formed on a semiconductor substrate. The substrate 202 may include various doping configurations depending on design requirements. For example, different doping profiles (e.g., n wells, p wells) may be formed on the substrate 202 in regions designed for different device types (e.g., n-type field effect transistors (NFET), p-type field effect transistors (PFET)). The suitable doping may include ion implantation of dopants and/or diffusion processes. The substrate 202 has isolation features (e.g., shallow trench isolation (STI) features) interposing the regions providing different device types. Further, the substrate 202 may be strained for performance enhancement, may include a silicon-on-insulator (SOI) structure, and/or have other suitable enhancement features.

At block 104, the example method 100 includes forming an epitaxial stack that includes a plurality of epitaxial layers over the substrate. Referring to the example of FIG. 3, in an embodiment of block 104, an epitaxial stack 212 is formed over the substrate 202. The epitaxial stack 212 includes sacrificial epitaxial layers 214 of a first composition interposed by channel epitaxial layers 216 of a second composition. The first and second composition can be different. In an embodiment, the sacrificial epitaxial layers 214 are formed from SiGe and the channel epitaxial layers 216 are formed from silicon (Si). However, other embodiments are possible including those that provide for a first composition and a second composition having different oxidation rates and/or etch selectivity. In some embodiments, the sacrificial epitaxial layer 214 includes SiGe and the channel epitaxial layer 216 includes silicon (Si). However, other embodiments are possible including those that provide for a first composition and a second composition having different oxidation rates and/or etch selectivity. In some embodiments, the sacrificial epitaxial layer 214 includes SiGe and where the channel epitaxial layer 216 includes Si, the Si oxidation rate of the channel epitaxial layer 216 is less than the SiGe oxidation rate of the sacrificial epitaxial layer 214. It is noted that three (3) layers each of epitaxial layers 214 and 216 are illustrated in FIG. 3, which is for illustrative purposes only and not intended to be limiting beyond what is specifically recited in the claims. In various embodiments, any number of epitaxial layers can be formed in the epitaxial stack 212; the number of layers depending on the desired number of channel regions for the structure 200. In some embodiments, the number of channel epitaxial layers 216 is between 1 and 5, such as 3, 4 or 5.

In some embodiments, the sacrificial epitaxial layer 214 has a thickness ranging from about 4 nm (nanometers) to about 12 nm. The sacrificial epitaxial layers 214 may be substantially uniform in thickness. In some embodiments, the channel epitaxial layer 216 has a thickness ranging from about 3 nm to about 6 nm. In some embodiments, the channel epitaxial layers 216 of the stack are substantially uniform in thickness.

As described in more detail below, the channel epitaxial layer 216 may serve as channel region(s) for a subsequently-formed multi-gate device and its thickness is chosen based on device performance considerations. The sacrificial epitaxial layer 214 may serve to reserve a spacing (or referred to as a gap) between adjacent channel region(s) for a subsequently-formed multi-gate device and its thickness is chosen based on device performance considerations.

By way of example, epitaxial growth of the epitaxial stack 212 may be performed by a molecular beam epitaxy (MBE) process, a metalorganic chemical vapor deposition (MOCVD) process, and/or other suitable epitaxial growth processes. In some embodiments, the epitaxially grown layers, such as the channel epitaxial layers 216, include the same material as the substrate 202, such as silicon (Si). In some embodiments, the epitaxially grown layers 214 and 216 include a different material than the substrate 202. As stated above, in at least some examples, the sacrificial epitaxial layer 214 includes an epitaxially grown Si₁₋ₓGeₓ layer (e.g., x is about 25~55%) and the channel epitaxial layer 216 includes an epitaxially grown Si layer. Alternatively, in some embodiments, either of the sacrificial epitaxial layers 214 and channel epitaxial layers 216 may include other materials such as germanium, a compound semiconductor such as silicon carbide, gallium arsenide, gallium phosphide, indium phosphide, indium arsenide, and/or indium antimonide, an alloy semiconductor such as SiGe, GaAsP, AlInAs, AlGaAs, InGaAs, GaInP, and/or GaInAsP, or combinations thereof. As discussed, the materials of the sacrificial epitaxial layers 214 and channel epitaxial layers 216 may be chosen based on providing differing oxidation and etch selectivity properties. In various embodiments, the epitaxial layers 214 and 216 are substantially dopant-free (i.e., having an extrinsic dopant concentration from about 0 cm⁻³ to about 1×10¹⁷ cm⁻³), where for example, no intentional doping is performed during the epitaxial growth process.

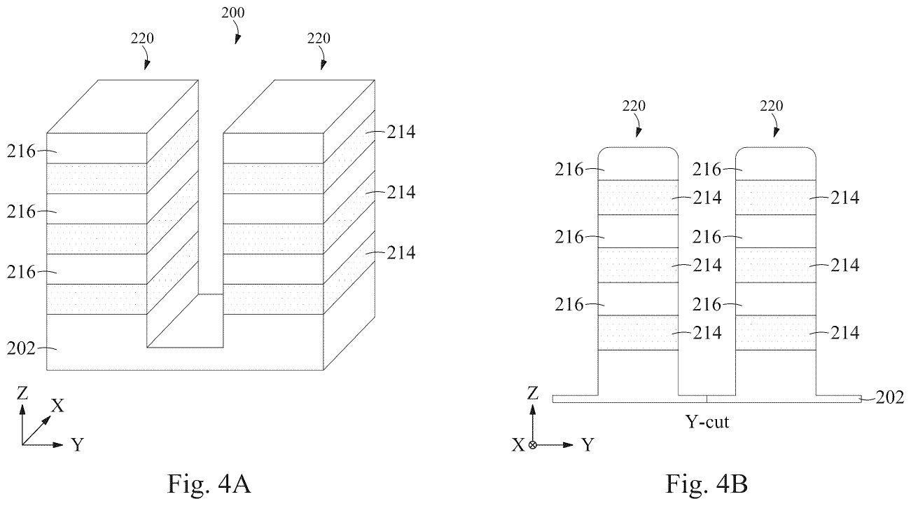

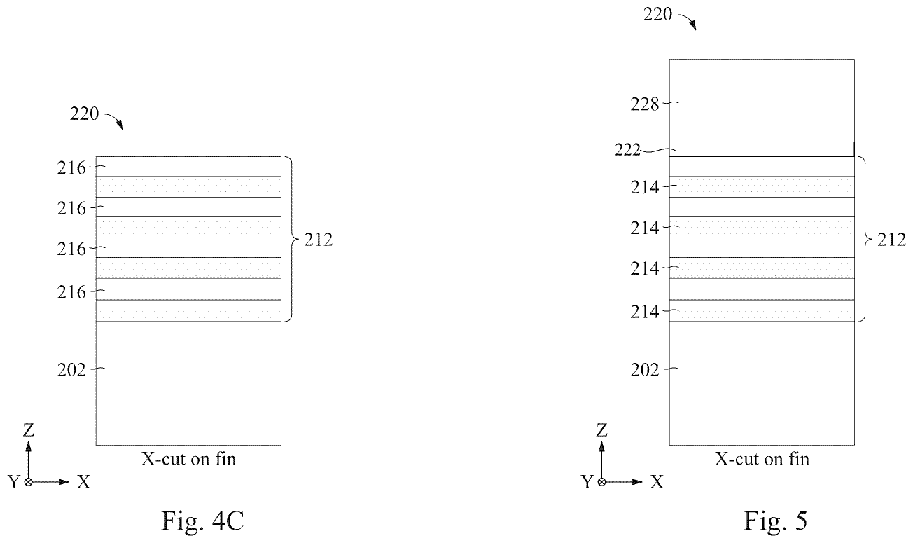

At block 106, the example method 100 includes patterning the epitaxial stack to form semiconductor fins (also referred to as fins). Referring to the example of FIGS. 4A, 4B, and 4C, in an embodiment of block 106, a plurality of fins 220 extending from the substrate 202 are formed. In various embodiments, each of the fins 220 includes an upper portion of the interleaved epitaxial layers 214 and 216 and a bottom portion protruding from the substrate 202.

The fins 220 may be fabricated using suitable processes including photolithography and etch processes. The photolithography process may include forming a photoresist layer over the substrate 202 (e.g., over the epitaxial stack 212), exposing the resist to a pattern, performing post-exposure bake processes, and developing the resist to form a masking element including the resist. In some embodiments, pattering the resist to form the masking element may be performed using an electron beam (e-beam) lithography process. The masking element may then be used to protect regions of the substrate 202, and epitaxial stack 212 formed thereupon, while an etch process forms trenches in unprotected regions through masking layer(s) such as hard mask, thereby leaving the plurality of extending fins. The trenches may be etched using a dry etch (e.g., reactive ion etching), a wet etch, and/or other suitable processes. The trenches may be filled with dielectric material forming, for example, shallow trench isolation features interposing the fins.

At block 108, the example method 100 includes forming one or more sacrificial layers/features over the substrate. Referring to the example of FIG. 5, in an embodiment of block 108, a sacrificial gate dielectric layer (not shown) is blanket deposited over an interlayer oxide 222, which is formed over the fin 220, which is formed over the substrate 202. A sacrificial gate electrode layer 228 is then blanket deposited on the sacrificial gate dielectric layer and over the substrate 202. The sacrificial gate electrode layer 228 includes silicon such as polycrystalline silicon or amorphous silicon. The thickness of the sacrificial gate dielectric layer is in a range from about 1 nm to about 5 nm in some embodiments. The thickness of the sacrificial gate electrode layer is in a range from about 100 nm to about 200 nm in some embodiments. In some embodiments, the sacrificial gate electrode layer is subjected to a planarization operation. The sacrificial gate dielectric layer and the sacrificial gate electrode layer 228 may be deposited using CVD, including LPCVD and PECVD, PVD, ALD, or other suitable processes.

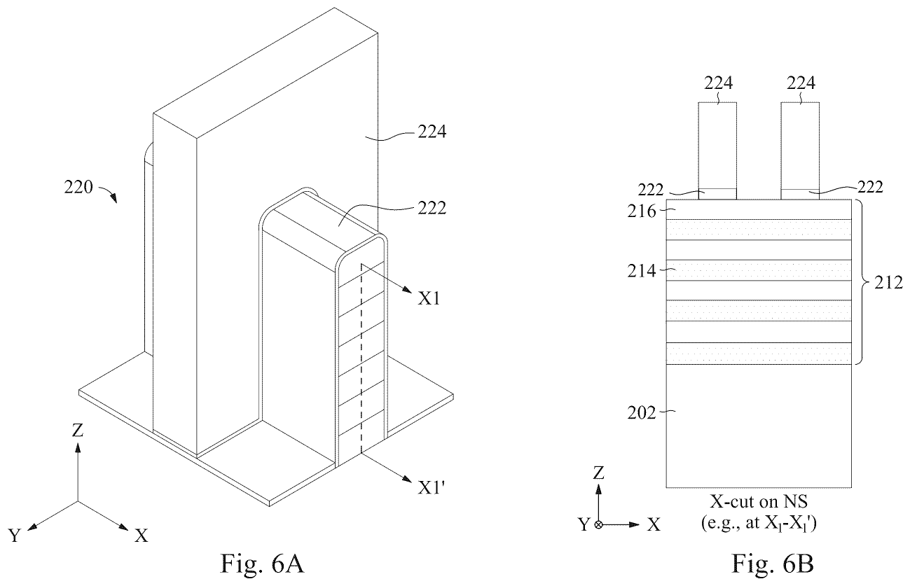

At block 110, the example method 100 includes patterning the one or more sacrificial layers/features to form a dummy gate structure on channel regions of the fins. Referring to the example of FIGS. 6A and 6B, in an embodiment of block 110, a sacrificial gate structure 224 is formed over portions of the fins 220 which are to be channel regions. The sacrificial gate structure 224 defines the channel regions of a GAA device. The sacrificial gate structure 224 includes a sacrificial gate dielectric layer and a sacrificial gate electrode layer 228. The sacrificial gate structure 224 is formed by forming a mask layer over the sacrificial gate electrode layer. The mask layer may include a pad silicon oxide layer and a silicon nitride mask layer. Subsequently, a patterning operation is performed on the mask layer and sacrificial gate dielectric and electrode layers are patterned into the sacrificial gate structure 224. By patterning the sacrificial gate structure 224, the fins 220 are partially exposed on opposite sides of the sacrificial gate structure 224, thereby defining source/drain (S/D) regions. In this disclosure, a source and a drain are interchangeably used, and the structures thereof are substantially the same.

The sacrificial gate structure 224 is subsequently removed as discussed with reference to block 130 of the method 100 and will be replaced by a final gate stack at a subsequent processing stage of the structure 200. In particular, the sacrificial gate structure 224 is replaced at a later processing stage by a high-K dielectric layer (HK) and metal gate electrode (MG) as discussed below.

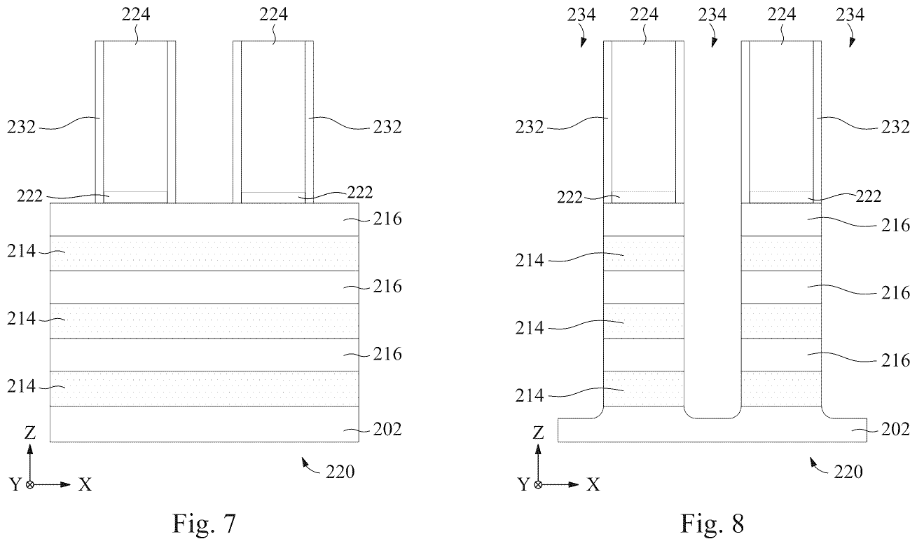

At block 112, the example method 100 includes forming gate sidewall spacers on sidewalls of the sacrificial gate structure. Referring to the example of FIG. 7, in an embodiment of block 112, gate sidewall spacers 232 are formed on sidewalls of the sacrificial gate structure 224. In various embodiments, the gate sidewall spacers 232 may include a dielectric material such as silicon oxide (SiOₓ), silicon nitride (SiN), silicon carbide (SiC), silicon oxynitride (SiON), SiCN films, silicon oxycarbide (SiOC), Silicon oxycarbonitride (SiOCN) films, and/or combinations thereof. In some embodiments, the gate sidewall spacers 232 include multiple layers, such as main spacer walls, liner layers, and the like. By way of example, the gate sidewall spacers 232 may be formed by depositing a dielectric material layer over the sacrificial gate structure 224 using processes such as, a CVD process, a sub atmospheric CVD (SACVD) process, a flowable CVD process, an ALD process, a PVD process, or other suitable process. In some embodiments, the deposition of the dielectric material layer is followed by an etching-back (e.g., anisotropically) process to expose portions of the fin 220 adjacent to and not covered by the sacrificial gate structure 224 (e.g., S/D regions). The dielectric material layer may remain on the sidewalls of the sacrificial gate structure 224 as gate sidewall spacers 232. In some embodiments, the etching-back process may include a wet etch process, a dry etch process, a multiple-step etch process, and/or a combination thereof. The gate sidewall spacers 232 may have a thickness ranging from about 5 nm to about 20 nm.

At block 114, the example method includes recessing the fins in the source drain/regions. Referring to the example of FIG. 8, in an embodiment of block 114, the fin 220 is recessed in the source drain/regions. The stacked epitaxial layers 214 and 216 are etched down at the S/D regions to form a recess 234. In various embodiments, the recessing is performed by a suitable etching process, such as a dry etching process, a wet etching process, or an RIE process. Dry etching may be implemented using an etchant including a bromine-containing gas (e.g., HBr and/or CHBR3), a fluorine-containing gas (e.g., CF₄, SF₆, CH₂F₂, CHF₃, and/or C₂F₆), other suitable gases, or combinations thereof.

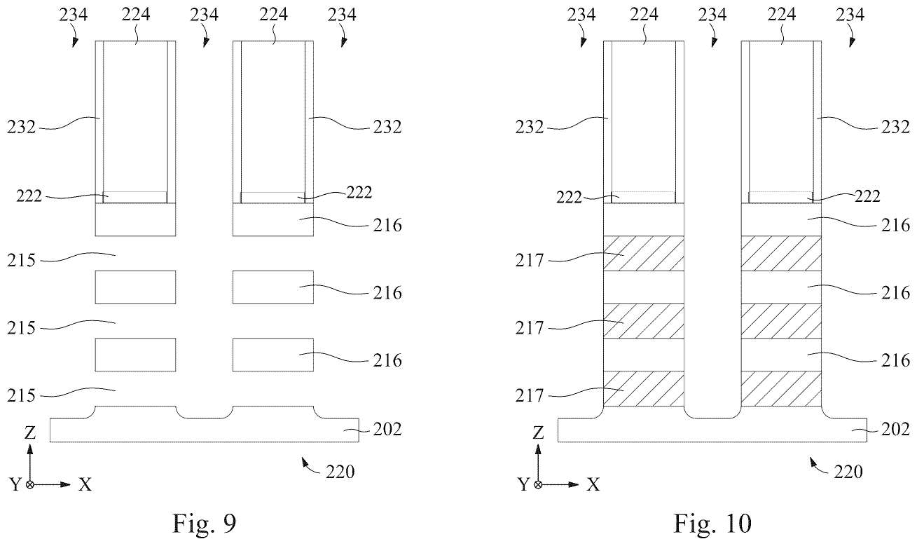

At block 116, the example method 100 includes removing the sacrificial epitaxial layers forming spaces between the channel epitaxial layers. Referring to the example of FIG. 9, in an embodiment of block 116, sacrificial epitaxial layers 214 have been removed and spaces 215 have been formed. The sacrificial epitaxial layers 214 can be removed or etched using an etchant that can selectively etch the sacrificial epitaxial layers 214 against the channel epitaxial layers 216.

When the sacrificial epitaxial layers 214 comprise Ge or SiGe and the channel epitaxial layers 216 comprise Si, the sacrificial epitaxial layers 214 can be selectively removed using a wet etchant such as, but not limited to, ammonium hydroxide (NH₄OH), tetramethylammonium hydroxide (TMAH), ethylenediamine pyrocatechol (EDP), or potassium hydroxide (KOH) solutions. In various embodiments, the plurality of sacrificial epitaxial layers 214 were selectively removed via a selective removal process that included oxidizing the plurality of sacrificial epitaxial layers 214 using a suitable oxidizer, such as ozone. Thereafter, the oxidized sacrificial epitaxial layers 214 were selectively removed via a dry etching process, for example, by applying an HCl gas at a temperature of about 500 degrees Celsius to about 700 degrees Celsius, or applying a gas mixture of CF₄, SF₆, and CHF₃.

At block 118, the example method 100 includes forming a sacrificial oxide layer (e.g., an oxide layer using well known deposition techniques, such as chemical vapor deposition (CVD), or possibly thermally grown, or using some other conventional technique) in area vacated by the removed sacrificial epitaxial layers. Referring to the example of FIG. 10, in an embodiment of block 118 a sacrificial oxide layer 217, such as silicon oxide or the like, is formed in area vacated by the removed sacrificial epitaxial layers 214. In various embodiments forming an oxide layer includes depositing the sacrificial oxide layer over the semiconductor structure 200 and etching back the sacrificial oxide layer such that the sacrificial oxide layer 217 remains between the channel epitaxial layers 216.

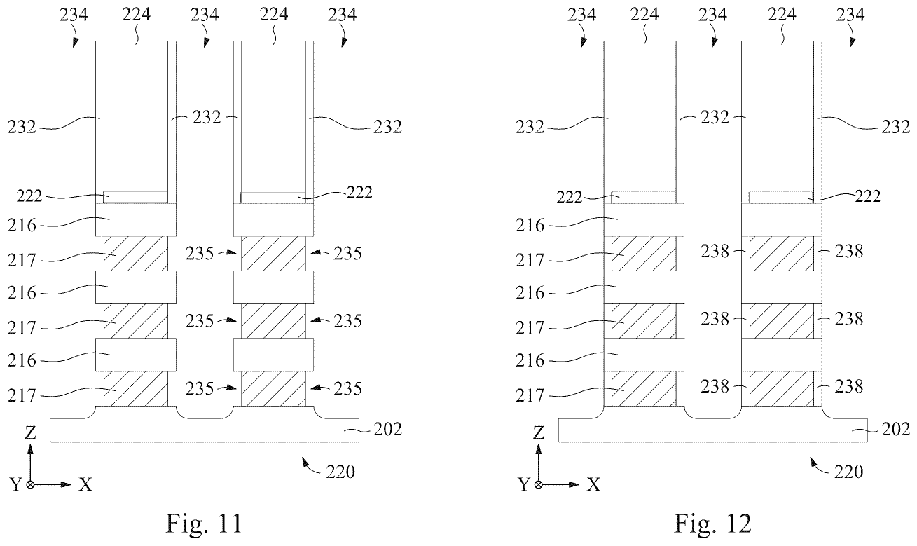

At block 120, the example method 100 includes forming a recess in the sacrificial oxide layers. Referring to the example of FIG. 11, in an embodiment of block 120, the sacrificial oxide layers 217 have been etched back forming oxide layer recesses 235 bounded on the top and bottom by channel epitaxial layers 216 and laterally by the recessed oxide layers 217. The oxide layers 217 can be selectively etched by using an etchant such as HF, NH₃, or a combination thereof.

At block 122, the example method 100 Includes forming an inner spacer layer in the oxide layer recesses. Forming the inner spacer layer may include depositing inner spacer material of a first material type in the oxide layer recesses, and trimming the inner spacer layers (e.g., via etching operations). Referring to the example of FIG. 12, in an embodiment of block 122, inner spacer layers 238 are formed in the oxide layer recesses 235. The inner spacer layers 238 may be formed from silicon oxides, silicon nitrides, silicon carbides, silicon carbide nitride, silicon oxide carbide, silicon carbide oxynitride, and/or other suitable dielectric materials. In some embodiments, the inner spacer layer 238 is deposited as a conformal layer. The inner spacer layers 238 can be formed by ALD or any other suitable method. In various embodiments, the inner spacer layers 238 are formed from the same material as the gate sidewall spacers 232. In various embodiments, the gate sidewall spacers 232 and the inner spacer layers 238 are formed from SiOCN.

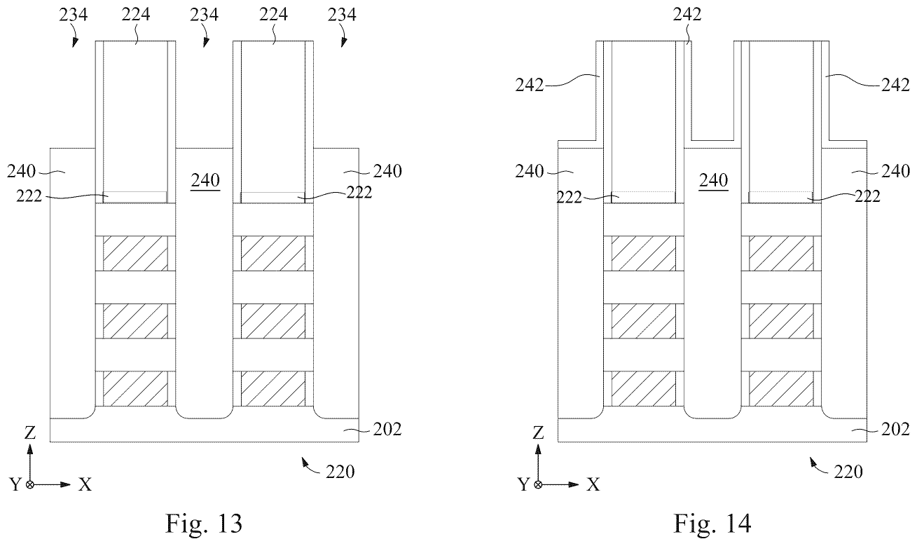

At block 124, the example method 100 Includes forming source/drain (S/D) features. Forming the S/D features may involve depositing pure silicon in the recess 234 in the source drain/regions. Referring to the example of FIG. 13, in an embodiment of block 124, epitaxial S/D features 240 are formed in recess 234. In some embodiments, the epitaxial S/D features 240 include silicon for NFETs and SiGe for PFETs. In some embodiments, the epitaxial S/D features 240 are formed by an epitaxial growth method using CVD, ALD, or molecular beam epitaxy (MBE). The epitaxial S/D features 240 are formed in contact with the channel epitaxial layers 216 and separated from the oxide layers 217 by the inner spacer layers 238.

At block 126, the example method 100 includes forming a CESL layer. Referring to the example of FIG. 14, in an embodiment of block 126, a CESL layer 242 is formed over the S/D features 240. The CESL layer 242 may comprise silicon nitride, silicon oxynitride, silicon nitride with oxygen (O) or carbon (C) elements, and/or other materials; and may be formed by CVD, PVD (physical vapor deposition), ALD, or other suitable methods. In various embodiments, the CESL layer 242 is formed from SiN.

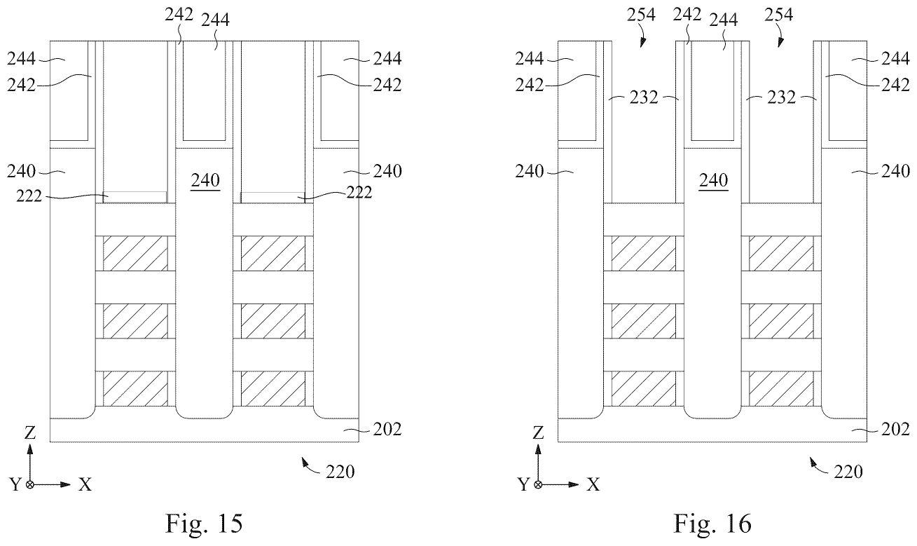

At block 128, the example method 100 includes forming an ILD layer. Referring to the example of FIG. 15, in an embodiment of block 128, an interlayer dielectric layer (ILD layer 244) is formed over the CESL layer 242. The ILD layer 244 may comprise tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 244 may be formed by PECVD, flowable CVD (FCVD), or other suitable methods. In some embodiments, forming the ILD layer 244 further includes performing a CMP process to planarize a top surface of the structure 200, such that the top surfaces of the sacrificial gate structure 224 are exposed.

At block 130, the example method 100 includes removing the dummy gate stack to form a gate trench. Referring to the example of FIG. 16, in an embodiment of block 130, the sacrificial gate structure 224 has been removed to form a gate trench 254. The gate trench 254 exposes the fin 220 in the channel region(s). The ILD0 layer 244 and the CESL layer 242 protects the epitaxial S/D features 240 during the removal of the sacrificial gate structure 224. The sacrificial gate structure 224 can be removed using plasma dry etching and/or wet etching. When the sacrificial gate electrode layer is polysilicon and the ILD0 layer 244 is an oxide, a wet etchant such as a TMAH solution can be used to selectively remove the sacrificial gate electrode layer. The sacrificial gate dielectric layer is thereafter removed using plasma dry etching and/or wet etching.

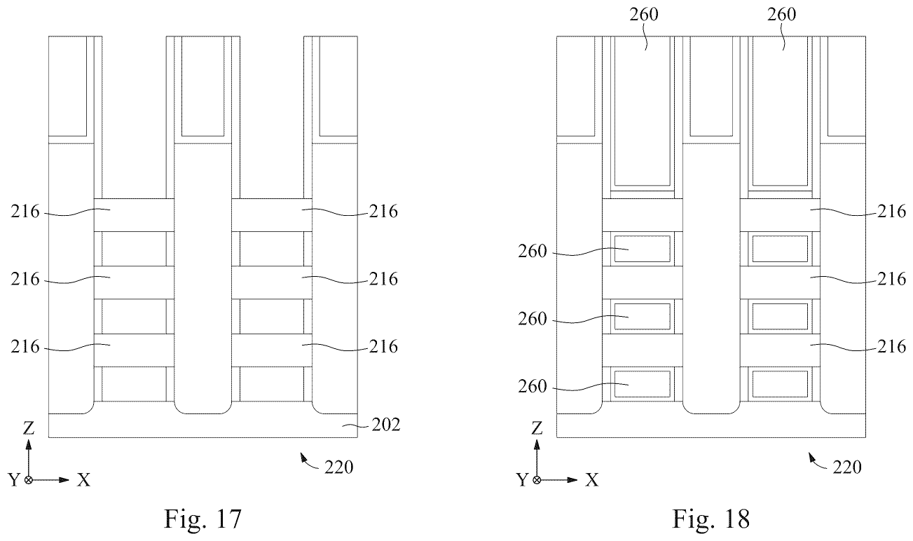

At block 132, the example method 100 includes removing the sacrificial oxide layers and releasing the nanosheets. Referring to the example of FIG. 17, in an embodiment of block 132, oxide layers 217 have been removed thereby releasing channel members from the channel region of the GAA device. In the illustrated embodiment, channel members are channel epitaxial layers 216 in the form of nanosheets. In various embodiments, the channel epitaxial layers 216 include silicon. In various embodiments, the plurality of sacrificial oxide layers 217 were selectively removed via a selective removal process that used an etchant such as HF, NH₃, or a combination thereof.

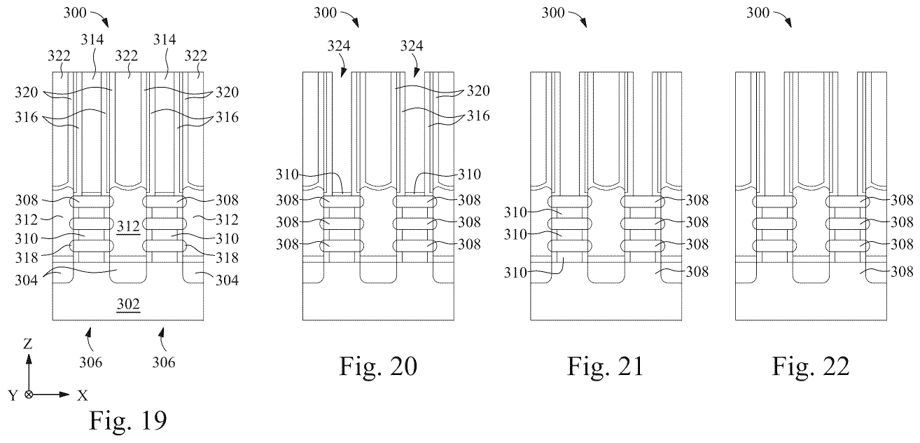

The removal of the sacrificial oxide layers is performed in a manner that can (a) prevent sheet notching/rounding on the top nanosheet, and (b) can prevent oxide from remaining between nanosheets for short channel and long channel devices and dielectric film damage for short channel devices. In various embodiments, removal of the sacrificial oxide layers includes a dry etching process for interlayer oxide removal (e.g., removal of interlayer oxide 222) and a wet+chemical etching process for oxide release (e.g., removal of sacrificial oxide layers 217), which is described in more detail below with regard to FIGS. 19-26.

At block 134, the example method 100 includes forming metal gate structures. Referring to the example of FIG. 18, in an embodiment of block 134, a gate structure 260 is formed. In various embodiments, the gate structure 260 is the gate of a multi-gate transistor. In various embodiments, the gate structure 260 is a high-K metal gate stack, however other compositions are possible. In various embodiments the high-K metal gate stack includes a gate dielectric layer that includes an interfacial layer and a high-k dielectric layer. The high-k dielectric layer wraps each of the nanosheets 216, and the interfacial layer is interposed between the high-k dielectric layer and the nanosheets 216. The interfacial layer may include a dielectric material such as silicon oxide (SiO₂) or silicon oxynitride (SiON), and may be formed by chemical oxidation, thermal oxidation, atomic layer deposition (ALD), CVD, and/or other suitable methods. The high-k dielectric layer may include hafnium oxide (HfO₂), hafnium silicon oxide (HfSiO), hafnium silicon oxynitride (HfSiON), hafnium tantalum oxide (HMO), hafnium titanium oxide (HfTiO), hafnium zirconium oxide (HfZrO), other suitable high-k dielectric materials, and/or combinations thereof. The high-k material may further be selected from metal oxides, metal nitrides, metal silicates, transition metal-oxides, transition metal-nitrides, transition metal-silicates, oxynitrides of metals, metal aluminates, zirconium silicate, zirconium aluminate, silicon oxide, silicon nitride, silicon oxynitride, zirconium oxide, titanium oxide, aluminum oxide, hafnium dioxide-alumina (HfO₂—Al₂O₃) alloy, other suitable materials, and/or combinations thereof. The high-k dielectric layer may be formed by any suitable process, such as atomic layer deposition (ALD), chemical vapor deposition (CVD), physical vapor deposition (PVD), remote plasma CVD (RPCVD), plasma enhanced CVD (PECVD), metal organic CVD (MOCVD), sputtering, plating, other suitable processes, and/or combinations thereof. In one embodiment, the gate dielectric layer is formed using a highly conformal deposition process such as ALD in order to ensure the formation of a gate dielectric layer having a uniform thickness around each channel layer. The high-K metal gate structures may include additional material layers.

At block 136, the example method 100 includes performing further fabrication. A semiconductor device may undergo further processing to form various features and regions known in the art. For example, subsequent processing may include filling the opening over the source/drain regions with ILD1 material to fill in the ILD1 layer and forming one or more intermetal dielectric (IMD) layers over the ILD1 layer. Each IMD layer may include an etch stop layer (ESL) above the underlying layer and an ILD layer above the ESL. The ESL may be deposited using one or more low temperature deposition processes such as chemical vapor deposition, physical vapor deposition, or atomic layer deposition. Subsequent processing may also include forming contact openings, contact metal, as well as various contacts/vias/lines and multilayer interconnect features (e.g., metal layers and interlayer dielectrics) on the substrate, configured to connect the various features to form a functional circuit that may include one or more multi-gate devices. In furtherance of the example, a multilayer interconnection may include vertical interconnects, such as vias or contacts, and horizontal interconnects, such as metal lines. The various interconnection features may employ various conductive materials including copper, tungsten, and/or silicide. In one example, a damascene and/or dual damascene process is used to form a copper related multilayer interconnection structure. Moreover, additional process steps may be implemented before, during, and after the method 100, and some process steps described above may be replaced or eliminated in accordance with various embodiments of the method 100.

FIG. 19-22 provide an embodiment of a process for removing the sacrificial oxide layers and releasing the nanosheets during fabrication of a GAA device. An example semiconductor structure 300 at an intermediate stage of fabrication is provided as illustrated in FIG. 19. The example semiconductor structure includes a substrate 302, silicon trench isolation features (STI features 304) disposed on the substrate 302 and separating a plurality of fin structures 306, channel epitaxial layers 308 stacked between sacrificial oxide layers 310, source drain regions 312, sacrificial gate structures (dummy gate structures 314), gate sidewall spacers 316, inner spacer layers 318, CESL 320, and ILD layers 322.

Subsequently, the sacrificial gate structures are removed, as illustrated in FIG. 20. The dummy gate structures 314 may be removed via a dry etching process leaving a gate trench 324. In this example, a portion of the sacrificial oxide layers 310 disposed above the top channel epitaxial layers 308 remain after the sacrificial gate structures are removed.

The method includes interlayer oxide removal via dry etching operations. In various embodiments, the dry etching operations for interlayer oxide removal include using an etch gas comprising one or more of CF₄, CHF₃, CH₂F₂, or others; using a passivation gas for selectivity comprising one or more of N₂, O₂, CO₂, or others; using a dilute gas comprising one or more of He, Ar, N₂, or others; at a power between approximately 10 W to approximately 1000 W; at a pressure of approximately 10 mTorr to approximately 800 mTorr; and a gas flow of approximately 20 sccm (standard cubic centimeter per minute) to approximately 2000 sccm. FIG. 21 depicts an example embodiment of the semiconductor structure 300 after the interlayer oxide removal via dry etching operations. The sacrificial oxide layers 310 above the top channel epitaxial layers 308 have been removed.

The method further includes oxide release operations that remove the sacrificial oxide layer from between the channel layers. The oxide release operations include wet and chemical etching operations. In various embodiments, the wet and chemical etching operations for oxide release include using an etch gas comprising one or more of HF, NH₃, or others; using a passivation gas for selectivity comprising one or more of N₂, O₂, CO₂, or others; using a dilute gas comprising one or more of He, Ar, N₂, or others; at a power between approximately 10 W to approximately 2000 W; at a pressure of approximately 10 mTorr to approximately 500 mTorr; and a gas flow of approximately 20 sccm to approximately 2000 sccm. FIG. 22 depicts an example embodiment of the semiconductor structure 300 after removal of the sacrificial oxide layer 310 from between the channel layers 308. The example semiconductor structure 300 at this stage of fabrication includes a square shape (e.g., with approximately 90 degree angles) between the gate sidewall spacers 316 and the top of the top channel epitaxial layer 308.

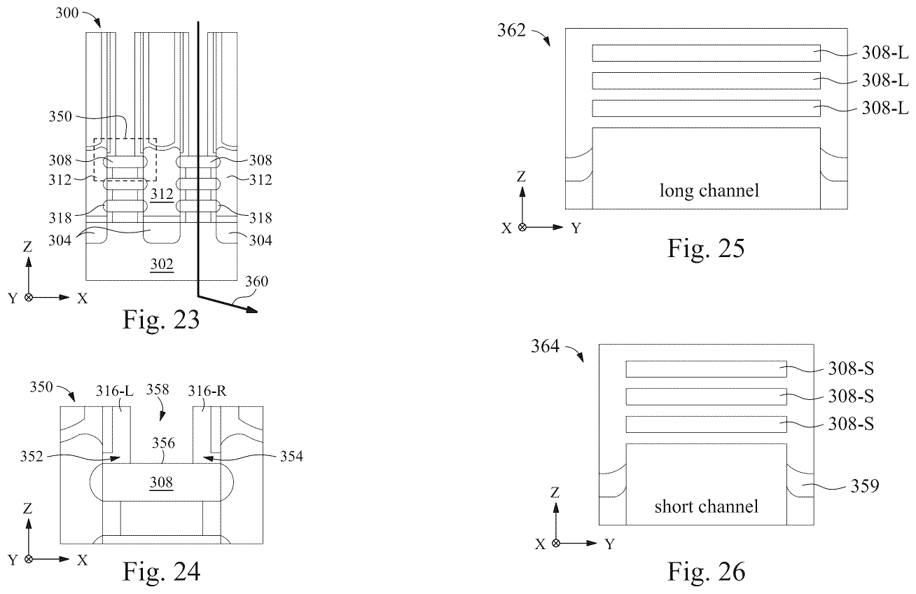

FIGS. 23-26 illustrate various features of the example semiconductor structure 300 after removal of the sacrificial oxide layer from between the channel layers. FIG. 23 depicts a magnified view of the example semiconductor structure 300 of FIG. 22, identifies a first region 350 around the gate sidewall spacers 316 and the top of the top channel epitaxial layer 308, and identifies a cut-line 360 along a y-axis across the channel epitaxial layers 308. FIG. 24 depicts a zoomed-in view of the first region 350, FIG. 25 depicts a cross-sectional view along cut-line 360 for a long channel device, and FIG. 26 depicts a cross-sectional view along cut-line 360 for a short channel device. As used herein, a long channel device comprises a transistor device with a channel length greater than 60 nm in the y-direction, and a short channel device comprises a transistor device with a channel length between about 19 nm to about 50 nm in the y-direction.

FIG. 24 illustrates that a corner 352 at the intersection between a first gate sidewall spacer 316-L and a top 356 of the top channel epitaxial layer 308 has an approximately 90° angle, a corner 354 at the intersection between a second gate sidewall spacer 316-R and the top 356 of the top channel epitaxial layer 308 has an approximately 90° angle, and the area 358 bounded on three sides by the first gate sidewall spacer 316-L, the top 356, and the second gate sidewall spacer 316-R has a rectangular-like shape.

FIG. 25 illustrates that a long-channel channel structure 362 formed using techniques described herein can be fabricated without oxide remaining between the different layers of the channel epitaxial layers 308-L as may be the case when a different technique is used to release the nanosheets.

Similarly, FIG. 26 illustrates that a short-channel channel structure 364 formed using techniques described herein can be fabricated without oxide remaining between the different layers of the channel epitaxial layers 308-S as may be the case when a different technique is used to release the nanosheets. FIG. 26 also illustrates a lack of damage to the dielectric film 359 around the channel regions that can occur when a different technique is used to release the nanosheets.

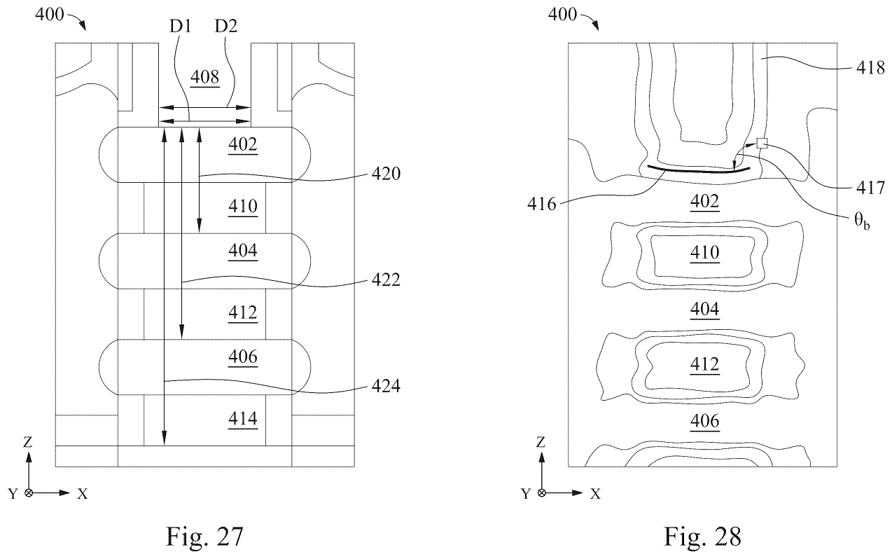

FIGS. 27-28 illustrate various features of an example semiconductor structure 400 (e.g., semiconductor structure 200 or semiconductor structure 300) after subsequent metal gate fabrication operations. Depicted are a channel structure and a metal gate structure. The channel structure comprises a first nanosheet 402, a second nanosheet 404, and a third nanosheet 406. The metal gate structure comprises a first metal gate region 408 disposed above the first nanosheet 402, a second metal gate region 410 disposed above the second nanosheet 404, a third metal gate region 412 disposed above the third nanosheet 406, and a fourth metal gate region 414 disposed below the third nanosheet 406. The first metal gate region 408 has a first length (D1) in the x-direction along a contact area 416 and a 2^{nd} length (D2) in the x-direction at a translation location 417 where a sidewall 418 of the first metal gate region 408 begins to transition (e.g., taper) toward the contact area 416. The semiconductor structure 400 further includes a first depth 420 measured from the transition location to the bottom of the second metal gate region 410, a second depth 422 measured from the transition location to the bottom of the third metal gate region 412, and a third depth 424 measured from the transition location to the bottom of the fourth metal gate region 414.

In various embodiments, the delta between the first length D1 (e.g., 13 nm) and the second length D2 (e.g., approximately 14 nm to approximately 15 nm) is less than 15% of the second length D2. In various embodiments, the delta between the first length D1 (e.g., 13 nm) and the second length D2 (e.g., approximately 14 nm to approximately 15 nm) is approximately 1 nm to approximately 2 nm or less. The lower delta results from a larger contact area 416 which reduces DIBL degradation, enlarges the electric current, can increase the manufacturing yield, and can improve device performance.

A corner angle θ_{b} measured at the corner between the sidewall 418 and the contact area 416 is close to 90°. In various embodiments, the corner angle θ_{b} is between approximately 90° and approximately 100°. A corner angle θ_{b} that is between approximately 90° and approximately 100° or closer to 90° can reduce DIBL degradation, enlarge the electric current, can increase the manufacturing yield, and can improve device performance. In various embodiments, the corner angle θ_{b} can be measured from a tangent line that crosses the sidewall 418 of first metal gate region 408 at the height at which the second length D2 is measured and the edge of contact area 416 that intersects with the sidewall 418.

In various embodiments, the first depth 420 is less than 15 nm, the second depth 422 is less than 30 nm, and the third depth 424 is less than 45 nm. In various embodiments, the first depth 420 is approximately 13 nm to approximately 14 nm, the second depth 422 is approximately 28 nm to approximately 29 nm, and the third depth 424 is approximately 43 nm to approximately 44 nm. A first depth less than 15 nm can indicate that shape rounding has not occurred and the contact area has a sufficient length to reduce DIBL degradation, enlarge the electric current, can increase the manufacturing yield, and can improve device performance. A first depth 420, a second depth 422, and a third depth 424 higher than these ranges can indicate that shape rounding has occurred near the intersection between the first metal gate region 408 and the top of the first nanosheet 402 resulting in DIBL degradation, reduced electric current, lower manufacturing yield, and lower device performance.

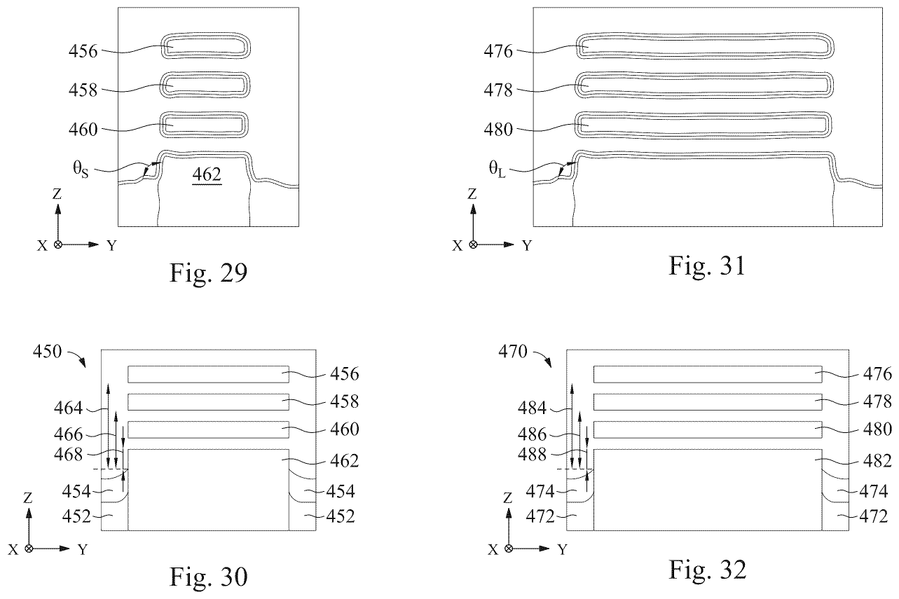

FIGS. 29-30 illustrate various features of an example short-channel semiconductor structure 450 (e.g., semiconductor structure 200 or semiconductor structure 300) after removal of the sacrificial oxide layer from between the channel layers. Depicted are a channel structure, STI 452, and a dielectric hard mask (e.g., nitride Si hard mask 454) disposed adjacent to a sidewall of a bottom structure of the plurality of vertically spaced channel structures. The channel structure comprises a first nanosheet 456, a second nanosheet 458, a third nanosheet 460, and a bottom channel region 462. The semiconductor structure 450 further includes a first depth 464 measured from the bottom of the first nanosheet 456 to the top of the nitride Si hard mask 454, a second depth 466 measured from the bottom of the second nanosheet 458 to the top of the nitride Si hard mask 454, a third depth 468 measured from the bottom of the third nanosheet 460 to the top of the nitride Si hard mask 454, and a bottom angle θ_{S} measured between a sidewall of the bottom channel region 462 and a top of the nitride Si hard mask 454.

In various embodiments, the bottom angle θ_{S} is between approximately 90° and approximately 99°. A bottom angle θ_{S} that is less than 100° can indicate that damage has not occurred to the nitride Si hard mask 454 during removal of the sacrificial oxide layer from between the channel layers resulting in reducing DIBL degradation, enlarged electric current, an increase in manufacturing yield, and improved device performance.

In various embodiments, the first depth 464 is approximately 45 nm, the second depth 466 is approximately 30 nm, and third depth 468 is approximately 15 nm. These depths indicate that damage has not occurred to the nitride Si hard mask 454 during removal of the sacrificial oxide layer from between the channel layers resulting in reducing DIBL degradation, enlarging electric current, an increase in manufacturing yield, and improved device performance. In various embodiments, a first depth 464 greater than 43 nm, a second depth 466 greater than 28 nm, and a third depth 468 greater than 15 nm indicate that damage has not occurred to the nitride Si hard mask 454 during removal of the sacrificial oxide layer from between the channel layers resulting in reducing DIBL degradation, enlarged electric current, an increase in manufacturing yield, and improved device performance.

FIGS. 31-32 illustrate various features of an example long-channel semiconductor structure 470 (e.g., semiconductor structure 200 or semiconductor structure 300) after removal of the sacrificial oxide layer from between the channel layers. Depicted are a channel structure, STI 472, and a dielectric hard mask (e.g., a nitride Si hard mask 474) disposed above the STI 472 and adjacent to a sidewall of a bottom structure of the plurality of vertically spaced channel structures. The channel structure comprises a first nanosheet 476, a second nanosheet 478, a third nanosheet 480, and a bottom channel region 482. The semiconductor structure 470 further includes a first depth 484 measured from the bottom of the first nanosheet 476 to the top of the nitride Si hard mask 474, a second depth 486 measured from the bottom of the second nanosheet 478 to the top of the nitride Si hard mask 474, a third depth 488 measured from the bottom of the third nanosheet 480 to the top of the nitride Si hard mask 474, and a bottom angle θ_{L} measured between a sidewall of the bottom channel region 482 and a top of the nitride Si hard mask 474.

In various embodiments, the bottom angle θ_{L} is between approximately 90° and approximately 95°. A bottom angle θ_{L} that is less than 100° can indicate that damage has not occurred to the nitride Si hard mask 474 during removal of the sacrificial oxide layer from between the channel layers resulting in reducing DIBL degradation, enlarged electric current, an increase in manufacturing yield, and improved device performance.

In various embodiments, the first depth 484 is approximately 44 nm, the second depth 486 is approximately 31 nm, and third depth 488 is approximately 18 nm. These depths can indicate that damage has not occurred to the nitride Si hard mask 474 during removal of the sacrificial oxide layer from between the channel layers resulting in reducing DIBL degradation, enlarged electric current, an increase in manufacturing yield, and improved device performance.

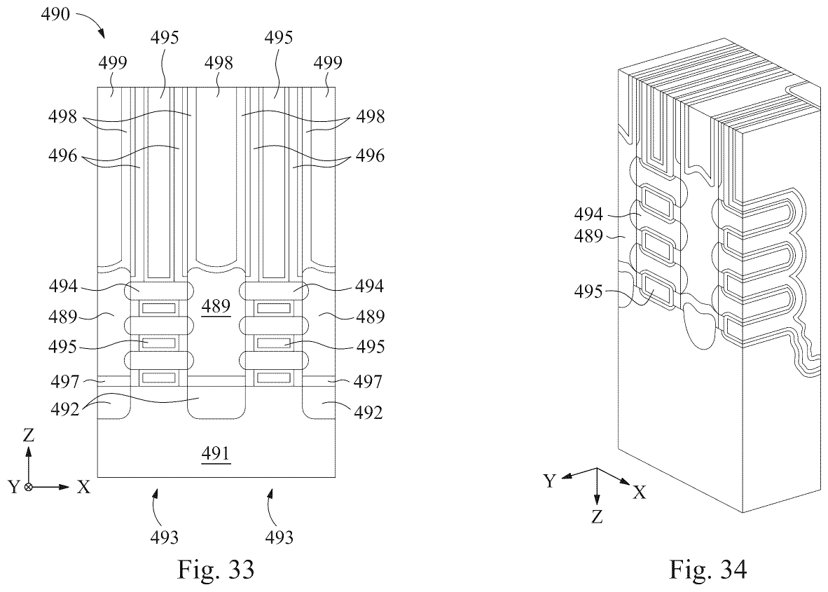

FIGS. 33-34 illustrate another example semiconductor structure 490 (e.g., semiconductor structure 200 or semiconductor structure 300) after subsequent metal gate fabrication operations. FIG. 33 provides a cross-sectional schematic view along the x-axis, and FIG. 34 provides a three dimensional schematic view. The example semiconductor structure 490 includes a substrate 491, STI features 492 disposed on the substrate 491 and separating a plurality of fin structures 493, channel nanosheets 494, high-K (HK) metal gate structures 495 (with HK dielectric, such as: HfO, TaN, and Metal, such as: W, Cu, Co) surrounding the channel nanosheets 494, source drain regions 489, gate sidewall spacers 496 (e.g.: SiCN, SiOCN, SiON, SiN), inner spacer layers 497 (e.g.: SiCN, SiOCN, SiON, SiN), CESL 498, and ILD layers 499.

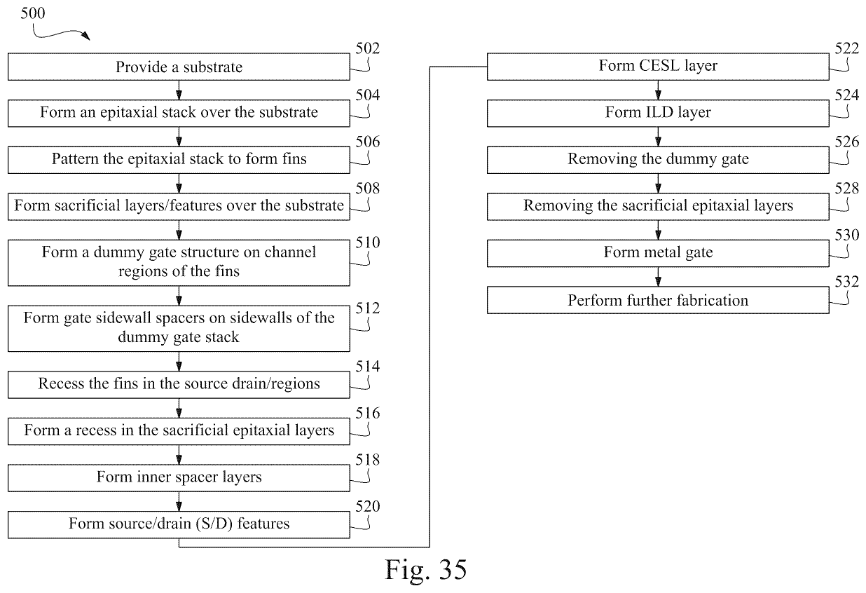

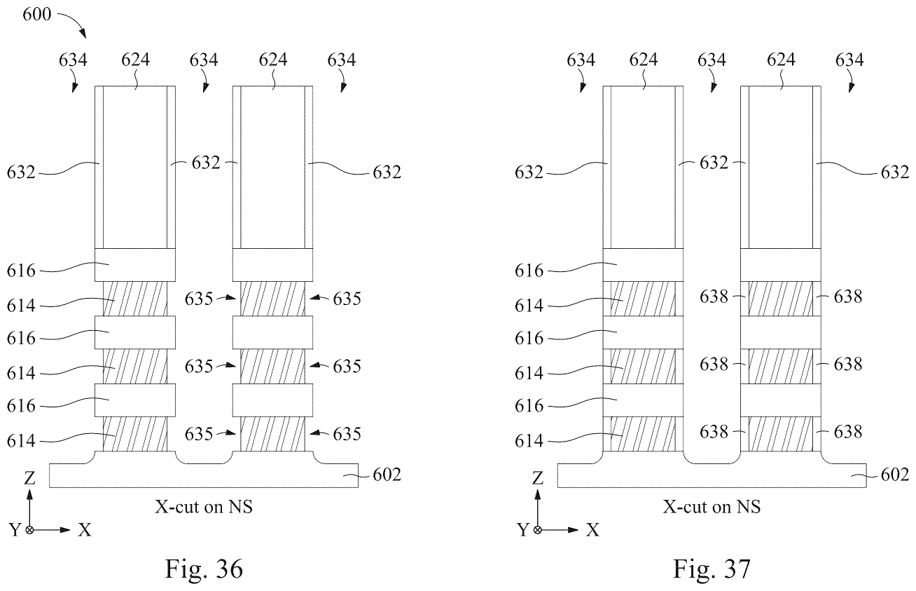

FIG. 35 is a flow chart depicting an example method 500 of semiconductor fabrication including fabrication of multi-gate devices, according to various aspects of the present disclosure. FIG. 35 is described in conjunction with FIGS. 36-38, which illustrate a semiconductor device 600 on a substrate 602 at various stages of fabrication in accordance with some embodiments, and FIG. 39, which describes an etching sequence. The method 500 is merely an example and is not intended to limit the present disclosure beyond what is explicitly recited in the claims. Additional steps may be provided before, during, and after method 500, and some of the steps described can be moved, replaced, or eliminated for additional embodiments of method 500. Additional features may be added in the semiconductor device 600 depicted in the figures, and some of the features described below can be replaced, modified, or eliminated in other embodiments. In some figures, some reference numbers of components or features illustrated therein may be omitted to avoid obscuring other components or features; this is for ease of depicting the figures.

At block 502, the example method 500 includes providing a substrate. This block is similar to block 102 of method 100 and reference is made to the corresponding description of block 102 for example description of block 502.

At block 504, the example method 500 includes forming an epitaxial stack that includes a plurality of epitaxial layers over the substrate. This block is similar to block 104 of method 100 and reference is made to the corresponding description of block 104 for example description of block 504.

At block 506, the example method 500 includes patterning the epitaxial stack to form semiconductor fins (also referred to as fins). This block is similar to block 106 of method 100 and reference is made to the corresponding description of block 106 for example description of block 506.

At block 508, the example method 500 includes forming one or more sacrificial layers/features over the substrate. This block is similar to block 108 of method 100 and reference is made to the corresponding description of block 108 for example description of block 508.

At block 510, the example method 500 includes patterning the one or more sacrificial layers/features to form a dummy gate structure on channel regions of the fins. The patterning operations include operations similar to those discussed with regard to block 110, but also includes operations that provide a higher level of smoothness to sidewalls of the sacrificial gate structure. The level of smoothness can be measured by a kink ratio in the dummy gate structure. The kink ratio of the dummy gate structure defines a level of deviation from a smooth surface and is based on changes in a horizontal position of a sidewall surface at a particular vertical location of the dummy gate structure versus an average horizontal position of the sidewall surface of the dummy gate structure along the length of the sidewall surface. In various embodiments, a kink is defined as a location on a vertically extending sidewall of the dummy gate structure where a particular sidewall location varies in horizontal location from the average horizontal position of a sidewall location a predetermined distance (e.g., 2 nm) above the particular location and the predetermined distance (e.g., 2 nm) below the particular sidewall location by at least 0.5 nm. In various embodiments, the kink ratio is based on the number of kinks over the length of the sidewall.

In various embodiments, the patterning operations comprise a bias reduction sequence that includes a main etching sequence, an O₂ ashing sequence to remove residue from the main etching sequence, a breakthrough etching sequence to etch the dummy gate structure to the top of the epitaxial stack, repeating smoothing etching operations followed by passivation operations (e.g., N₂ passivation) a plurality of times (e.g., 3 times) to make the sidewalls of the dummy gate structure smoother and to reduce the kink ratio, and an over etching sequence. Referring to the example of FIG. 39, in an embodiment of the pattering operations, an example bias reduction sequence 700 is provided for reducing a kink ratio on a dummy gate structure. The example recipe sequence 700 includes: at 702, a main etching sequence; at 704, an ashing process using O₂ followed by a breakthrough etching sequence; at 706, a first soft landing etching sequence, which smooths out the sidewalls of the dummy gate structure; at 708, a first N₂ passivation sequence; at 710, a second soft landing etching sequence, which further smooths out the sidewalls of the dummy gate structure; at 712, a second N₂ passivation sequence; at 714, a third soft landing etching sequence, which further smooths out the sidewalls of the dummy gate structure; at 716, a third N₂ passivation sequence; and at 718 an over etching sequence, which further smooths out the sidewalls of the dummy gate structure.

In various embodiments, the main etching sequence, smoothing etching operations, and the over etching sequence comprise plasma etching and are performed using an etch gas comprising one or more of CF₄, CHF₃, CH₂F₂, Cl₂, HBr, O₂ or others with approximately 5% to approximately 10% HBr; using a passivation gas for selectivity comprising one or more of N₂, O₂, CO₂, or others; using a dilute gas comprising one or more of He, Ar, N₂, or others; at a power between approximately 10 W to approximately 4000 W; at a pressure of approximately 1 mTorr to approximately 800 mTorr; and a gas flow of approximately 20 sccm to approximately 3000 sccm. In various embodiments, the patterning operations may reduce a kink ratio to less than 10%.

At block 512, the example method 500 includes forming gate sidewall spacers on sidewalls of the sacrificial gate structure. This block is similar to block 112 of method 100 and reference is made to the corresponding description of block 112 for example description of block 512. Because the dummy gate 624 was formed with a reduced kink ratio, the inner sidewalls of the inner spacer layers 638 are formed with a smooth surface and a reduced kink ratio. In various embodiments, the level of smoothness of the sidewalls of the sacrificial gate structure are transferred to sidewalls of the gate sidewall spacers. In various embodiments, the kink ratio of the sidewalls of the sacrificial gate structure are transferred to the side walls of the gate sidewall spacers.

The level of smoothness can be measured by a kink ratio in the gate sidewall spacers. The kink ratio of the gate sidewall spacers defines a level of deviation from a smooth surface and is based on changes in a horizontal position of a sidewall surface at a particular vertical location of the gate sidewall spacers versus an average horizontal position of the sidewall surface of the gate sidewall spacers along the length of the sidewall surface. In various embodiments, a kink is defined as a location on a vertically extending sidewall where a particular sidewall location varies in horizontal location from the average horizontal position of a sidewall location a predetermined distance (e.g., 2 nm) above the particular location and the predetermined distance (e.g., 2 nm) below the particular sidewall location by at least 0.5 nm. In various embodiments, the kink ratio is based on the number of kinks over the length of the sidewall.

At block 514, the example method includes recessing the fins in the source drain/regions. This block is similar to block 114 of method 100 and reference is made to the corresponding description of block 114 for example description of block 514.

At block 516, the example method 500 includes forming a recess in the sacrificial epitaxial layers (e.g., SiGe) of the epitaxial stack. Referring to the example of FIG. 36, in an embodiment of block 516, the sacrificial epitaxial layers 614 have been etched back forming sacrificial epitaxial layer recesses 635 bounded on the top and bottom by channel epitaxial layers 616 and laterally by the recessed sacrificial epitaxial layers 614. The sacrificial epitaxial layers 614 can be selectively etched by using a wet etchant such as, but not limited to, ammonium hydroxide (NH₄OH), tetramethylammonium hydroxide (TMAH), ethylenediamine pyrocatechol (EDP), or potassium hydroxide (KOH) solutions. Alternatively, at block 516, lateral ends of the sacrificial epitaxial layers 614 that are exposed in the recess 634 may be selectively oxidized to increase the etch selectivity between the epitaxial layers 614 and 616. In some examples, the oxidation process may be performed by exposing the device 600 to a wet oxidation process, a dry oxidation process, or a combination thereof.

At block 518, the example method 500 Includes forming an inner spacer layer in the sacrificial epitaxial layer recesses. Forming the inner spacer layer may include depositing inner spacer material of a first material type in the sacrificial epitaxial layer recesses, and trimming the inner spacer layers (e.g., via etching operations). Referring to the example of FIG. 37, in an embodiment of block 518, inner spacer layers 638 are formed in the sacrificial epitaxial layer recesses 635. The inner spacer layers 638 may be formed from silicon oxides, silicon nitrides, silicon carbides, silicon carbide nitride, silicon oxide carbide, silicon carbide oxynitride, and/or other suitable dielectric materials. In some embodiments, the inner spacer layer 638 is deposited as a conformal layer. The inner spacer layers 638 can be formed by ALD or any other suitable method. In various embodiments, the inner spacer layers 638 are formed from the same material as the gate sidewall spacers 632, which surround the dummy gate 624. In various embodiments, the gate sidewall spacers 632 and the inner spacer layers 638 are formed from SiOCN.

At block 520, the example method 500 Includes forming source/drain (S/D) features. This block is similar to block 124 of method 100 and reference is made to the corresponding description of block 124 for example description of block 520.

At block 522, the example method 500 includes forming a CESL layer. This block is similar to block 126 of method 100 and reference is made to the corresponding description of block 126 for example description of block 522.

At block 524, the example method 500 includes forming an ILD layer. This block is similar to block 128 of method 100 and reference is made to the corresponding description of block 128 for example description of block 524.

At block 526, the example method 500 includes removing the dummy gate 624 to form a gate trench. This block is similar to block 130 of method 100 and reference is made to the corresponding description of block 130 for example description of block 526. Because the dummy gate 624 was formed with a reduced kink ratio, the inner sidewalls of the inner spacer layers 638 retain a smooth surface and a reduced kink ratio.

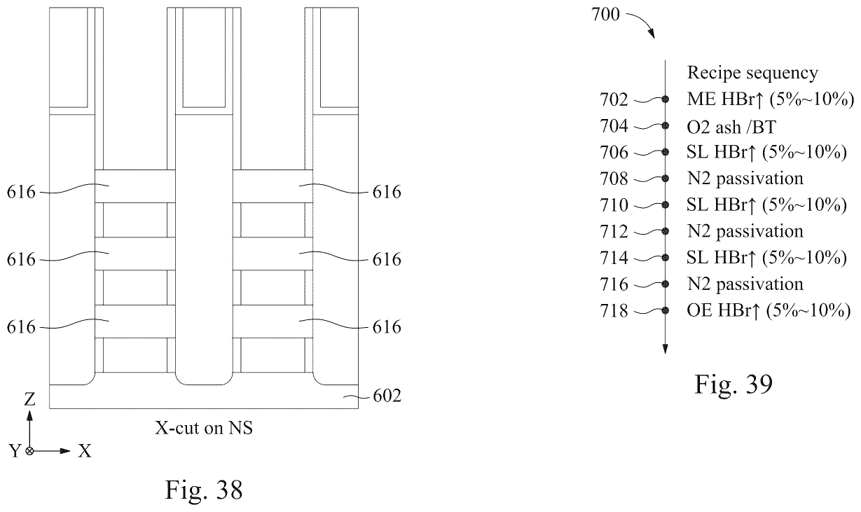

At block 528, the example method 500 includes removing the sacrificial epitaxial layers to form nanosheets. Referring to the example of FIG. 38, in an embodiment of block 528, sacrificial epitaxial layers 614 have been removed thereby releasing channel members from the channel region of the GAA device. In the illustrated embodiment, channel members are channel epitaxial layers 616 in the form of nanosheets. In various embodiments, the channel epitaxial layers 616 include silicon, and the sacrificial epitaxial layers 614 include silicon germanium. In various embodiments, the plurality of sacrificial epitaxial layers 614 were selectively removed via a selective removal process that included oxidizing the plurality of sacrificial epitaxial layers 614 using a suitable oxidizer, such as ozone. Thereafter, the oxidized sacrificial epitaxial layers 614 were selectively removed via a dry etching process, for example, by applying an HCl gas at a temperature of about 500 degrees Celsius to about 700 degrees Celsius, or applying a gas mixture of CF₄, SF₆, and CHF₃.

At block 530, the example method 500 includes forming metal gate structures. This block is similar to block 134 of method 100 and reference is made to the corresponding description of block 134 for example description of block 530. Because the dummy gate 624 was formed with a reduced kink ratio and the inner sidewalls of the inner spacer layers 638 are formed with a smooth surface and a reduced kink ratio, the sidewalls of the metal gate structures are formed with a smooth surface and a reduced kink ratio.

In various embodiments, a level of smoothness of the sidewalls of the gate spacers are transferred to sidewalls of the metal gate structure. The level of smoothness can be measured by a kink ratio in the metal gate structure. The kink ratio of the metal gate structure defines a level of deviation from a smooth surface and is based on changes in a horizontal position of a sidewall surface at a particular vertical location of the metal gate structure versus an average horizontal position of the sidewall surface of the metal gate structure along the length of the sidewall surface. In various embodiments, a kink is defined as a location on a vertically extending sidewall of the metal gate structure where a particular sidewall location varies in horizontal location from the average horizontal position of a sidewall location a predetermined distance (e.g., 2 nm) above the particular location and the predetermined distance (e.g., 2 nm) below the particular sidewall location by at least 0.5 nm. In various embodiments, the kink ratio is based on the number of kinks over the length of the sidewall.

At block 532, the example method 500 includes performing further fabrication. This block is similar to block 136 of method 100 and reference is made to the corresponding description of block 136 for example description of block 532. Further fabrication includes forming a metal drain (MD) contact. Because the sidewalls of the metal gate structures were formed with a smooth surface and a reduced kink ratio, the MG vertical profile maintains a certain distance from the MD. This can result in reduced MD-MG leakage and damage.

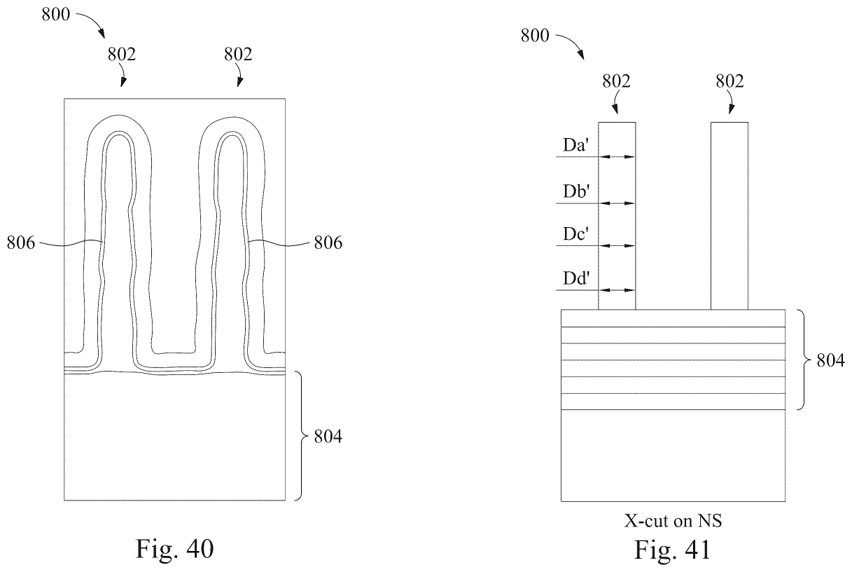

FIGS. 40 and 41 are cross-sectional views of a semiconductor structure 800 depicting a plurality of dummy gate structures 802 disposed over an epitaxial stack 804. As illustrated, the dummy gate structures have a variable thickness and sidewalls 806 that are not smooth due to the variable thickness of the gate structures. FIG. 41 is a schematic view of the semiconductor structure 800 illustrating the variable thickness of the dummy gate structures 802. In this example, the gate structures include a first thickness Dₐ at a first height level of the gate structure, a second thickness D_{b} at a second height level of the gate structure, a third thickness D_{c} at a third height level of the gate structure, and a fourth thickness D_{d} at a fourth height level of the gate structure. Because of the use of a bias reduction sequence when patterning the dummy gate structures 802, the kink ratio is 10% or less.

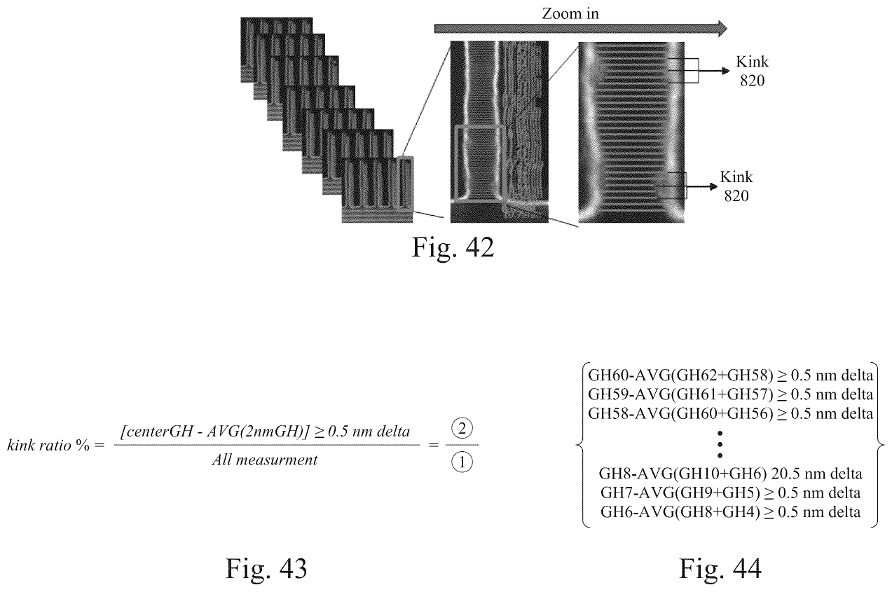

FIG. 42 is a cross-section schematic diagram illustrating example kink characteristics of dummy gates on a semiconductor structure. FIG. 43 is a diagram depicting an example formula for determining a kink ratio. FIG. 44 is a diagram depicting example calculations made using the formula of FIG. 43. As illustrated in FIG. 42, a kink 820 provides a measure of the difference between dummy gate widths at different heights of the dummy gate. As illustrated in FIG. 43, the kink ratio is based on the number of kink deltas having a difference greater than or equal to 0.5nm, wherein a kink delta is the difference between a width at a center height of a kink and the average of the width at a height 2 nm above the kink and the width at a height 2 nm below the kink. The kink ratio is equal to the number of kinks in a dummy gate structure having a Kink delta greater than 0.5 nm divided by the length of the dummy gate structure.

In various embodiments, the number of kinks having a delta greater than or equal to 0.5 nm may be 1E7 (10,000,000) or less when a bias reduction sequence is used during dummy gate patterning operations versus the number of kinks having a delta greater than or equal to 0.5 nm being 1E10 when a bias reduction sequence is not used during dummy gate patterning operations. A lower kink ratio and lower number of kinks can result in a lower likelihood of a leak path between a MG and MD and improved device yield during manufacturing.

In various embodiments, the kink ratio for a dummy gate structure may be 10% or less when a bias reduction sequence is used during dummy gate patterning operations versus a kink ratio of 30-40% when a bias reduction sequence is not used during dummy gate patterning operations. A lower kink ratio and lower number of kinks can result in a lower likelihood of a leak path between a MG and MD and improved device yield during manufacturing.

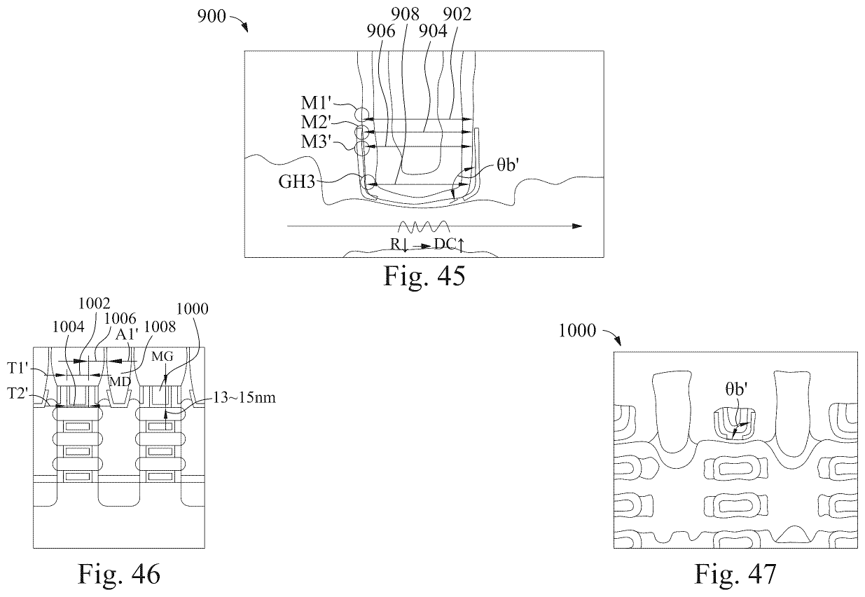

FIG. 45 is a cross-sectional schematic diagram depicting an example metal gate structure (MG 900) that has been formed after a bias reduction sequence was used during dummy gate patterning operations. In this example, a bottom angle θ_{b} is defined between a sidewall of the MG 900 and a contact surface of the MG 900, a width 902 is defined at a gate height of 25 nm, a width 904 is defined at a gate height of 20 nm, a width 906 is defined at a gate height of 15 nm, and a width 908 is defined at a gate height of 3 nm. In this example, the gate structure has a M1 delta (the delta between width 902 and width 908) of approximately 3 nm to approximately 4 nm, M2 delta (the delta between width 904 and width 908) of approximately 1 nm to approximately 2 nm, a M3 delta (the between width 906 and width 908) of less than 1 nm, and a bottom angle θ_{b} between approximately 95° to approximately 105°. These ranges for M1 delta, M2 delta, M3 delta, and bottom angle θ_{b} can allow for a lower likelihood of a leak path between a MG and MD and improved device yield during manufacturing. In various embodiments, a bottom angle θ_{b} of less than 110 degrees may allow for a lower likelihood of a leak path between a MG and MD and improved device yield during manufacturing.

In various embodiments, a M1 delta of less than 5 nm may allow for a lower likelihood of a leak path between a MG and MD and improved device yield during manufacturing. In various embodiments, a M2 delta of less than 3 nm may allow for a lower likelihood of a leak path between a MG and MD and improved device yield during manufacturing. In various embodiments, an M3 delta of less than 2 nm may allow for a lower likelihood of a leak path between an MG and MD and improved device yield during manufacturing.

FIGS. 46 and 47 are schematic cross-sectional views depicting an example metal gate structure (MG 1000) that has been formed after a bias reduction sequence was used during dummy gate patterning operations. In this example, a bottom angle θ_{b} is defined between a sidewall of the MG 1000 and a contact surface of the MG 1000, a width 1002 is defined at the top of the MG 1000, a width 1004 is defined at the bottom of the MG 1000, a width 1006 is defined between the MG 1000 and the MD 1008. In this example, the gate structure has a T1 to T2 delta (the delta between width 902 and width 904) of less than 1 nm, MG to MD distance of approximately 7.5 nm to approximately 9.5 nm, and a bottom angle θ_{b} between approximately 95° to approximately 105°. These ranges for T1 to T2 delta, MG to MD distance, and bottom angle θ_{b} can allow for a lower likelihood of a leak path between a MG and MD and improved device yield during manufacturing.

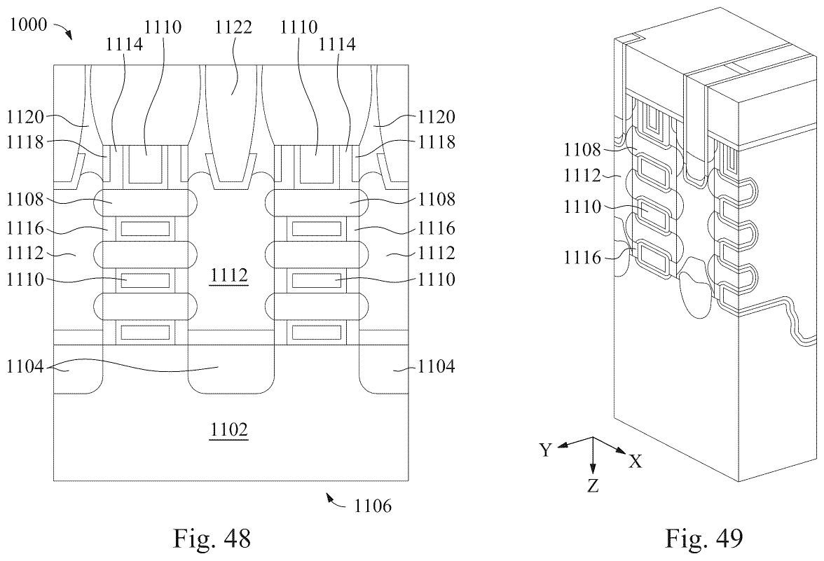

FIGS. 48 and 49 illustrate another example semiconductor structure 1100 after metal gate fabrication operations when a bias reduction sequence was used during dummy gate patterning operations. FIG. 48 provides a cross-sectional schematic view along the x-axis, and FIG. 49 provides a three dimensional schematic view. The example semiconductor structure 1100 includes a substrate 1102, STI features 1104 disposed on the substrate 1102 and separating a plurality of fin structures 1106, channel nanosheets 1108, high-K (HK) metal gate structures 1110 (with HK dielectric, such as: HfO, TaN, and Metal, such as: W, Cu, Co) surrounding the channel nanosheets 1108, source drain regions 1112, gate sidewall spacers 1114 (e.g.: SiCN, SiOCN, SiON, SiN), inner spacer layers 1116 (e.g.: SiCN, SiOCN, SiON, SiN), CESL 1118, ILD layers 1120, and MD 1122.

In some aspects, the techniques described herein relate to a semiconductor structure, including: a channel region including a plurality of vertically spaced channel structures surrounded by a gate structure including a top vertically spaced channel structure; and a first metal gate region of the gate structure disposed above the top vertically spaced channel structure, the first metal gate region including: a vertically extending sidewall; a horizontally extending contact area at a bottom of the first metal gate region that contacts the top vertically spaced channel structure, the contact area having a first length that extends horizontally; a transition location on the sidewall at a location where the sidewall begins to transition toward the contact area; and a second length that extends horizontally across the first metal gate region at the transition location; wherein a difference between the first length and the second length is less than 15% of the second length.

In some aspects, the techniques described herein relate to a semiconductor structure, further including a corner angle measured at a corner between the sidewall and the contact area, wherein the corner angle is less than 100 degrees.

In some aspects, the techniques described herein relate to a semiconductor structure, further including a first depth measured from the transition location to a bottom of a second metal gate region disposed below the top vertically spaced channel structure, wherein the first depth is less than 15 nm.

In some aspects, the techniques described herein relate to a semiconductor structure, further including a second depth measured from the transition location to a bottom of a third metal gate region disposed below a second vertically spaced channel structure disposed below the top vertically spaced channel structure, wherein the second depth is less than 30 nm.

In some aspects, the techniques described herein relate to a semiconductor structure, further including a third depth measured from the transition location to a bottom of a fourth metal gate region disposed below a third vertically spaced channel structure disposed below the second vertically spaced channel structure, wherein the third depth is less than 45 nm.

In some aspects, the techniques described herein relate to a semiconductor structure, wherein the difference between the first length and the second length is between approximately 1 nm and approximately 2 nm.

In some aspects, the techniques described herein relate to a method, including: providing a semiconductor structure including a plurality of vertically spaced channel structures, a plurality of vertically spaced interlayer oxide regions positioned between the plurality of vertically spaced channel structures, a sacrificial gate structure disposed above the plurality of vertically spaced channel structures, a source feature, and a drain feature; removing the sacrificial gate structure via dry etching operations; removing interlayer oxide above a top channel structure of the plurality of vertically spaced channel structures via dry etching operations; and removing remaining portions of the plurality of vertically spaced interlayer oxide regions via chemical etching operations.

In some aspects, the techniques described herein relate to a method, wherein removing remaining portions of the plurality of vertically spaced interlayer oxide regions via chemical etching operations includes removing all remaining portions of the plurality of vertically spaced interlayer oxide regions via the chemical etching operations.

In some aspects, the techniques described herein relate to a method, wherein removing remaining portions of the plurality of vertically spaced interlayer oxide regions via chemical etching operations includes removing the plurality of vertically spaced interlayer oxide regions without creating a recess between a bottom structure of the plurality of vertically spaced channel structures and a dielectric film adjacent to sidewalls of the bottom structure.

In some aspects, the techniques described herein relate to a method, wherein the semiconductor structure after removing remaining portions of the plurality of vertically spaced interlayer oxide regions via chemical etching operations includes an angle between a sidewall of a bottom structure of the plurality of vertically spaced channel structures and a dielectric film disposed adjacent to the sidewall and the angle is less than 100 degrees.

In some aspects, the techniques described herein relate to a method, wherein the semiconductor structure after removing remaining portions of the plurality of vertically spaced interlayer oxide regions via chemical etching operations further includes a dielectric film disposed adjacent to a sidewall of a bottom channel structure of the plurality of vertically spaced channel structures and a first depth measured from a bottom of a top channel structure of the plurality of vertically spaced channel structures to a top of the dielectric film, wherein the first depth is approximately 45 nm.

In some aspects, the techniques described herein relate to a method, wherein the semiconductor structure after removing remaining portions of the plurality of vertically spaced interlayer oxide regions via chemical etching operations further includes a dielectric film disposed adjacent to a sidewall of a bottom channel structure of the plurality of vertically spaced channel structures and a second depth measured from a bottom of a second channel structure of the plurality of vertically spaced channel structures to a top of the dielectric film, wherein the second depth is approximately 30 nm.

In some aspects, the techniques described herein relate to a method, wherein the semiconductor structure after removing remaining portions of the plurality of vertically spaced interlayer oxide regions via chemical etching operations further includes a dielectric film disposed adjacent to a sidewall of a bottom channel structure of the plurality of vertically spaced channel structures and a third depth measured from a bottom of a third channel structure of the plurality of vertically spaced channel structures to a top of the dielectric film, wherein the third depth is approximately 15 nm.

In some aspects, the techniques described herein relate to a method, including: providing a semiconductor structure including a plurality of vertically spaced channel structures, a plurality of vertically spaced interlayer oxide regions positioned between the plurality of vertically spaced channel structures, a sacrificial gate structure disposed above the plurality of vertically spaced channel structures, a source feature, and a drain feature; removing the sacrificial gate structure via dry etching operations; removing interlayer oxide above a top channel structure of the plurality of vertically spaced channel structures via dry etching operations; removing remaining portions of the plurality of vertically spaced interlayer oxide regions via chemical etching operations; and forming a metal gate structure around the plurality of vertically spaced channel structures, the metal gate structure including a first metal gate region disposed above a top vertically spaced channel structure of the plurality of vertically spaced channel structures, the first metal gate region including: a vertically extending sidewall; a horizontally extending contact area at a bottom of the first metal gate region that contacts the top vertically spaced channel structure; and a corner angle measured at a corner between the sidewall and the contact area that is less than 100 degrees.

In some aspects, the techniques described herein relate to a method, wherein: the contact area includes a first length that extends horizontally; the first metal gate region further includes a transition location on the sidewall at a location where the sidewall begins to transition toward the contact area; the first metal gate region further includes a second length that extends horizontally across the first metal gate region at the transition location; and a difference between the first length and the second length is less than 15% of the second length.

In some aspects, the techniques described herein relate to a method, wherein the first metal gate region further includes a first depth measured from the transition location to a bottom of a second metal gate region disposed below the top vertically spaced channel structure, wherein the first depth is less than 15 nm.

In some aspects, the techniques described herein relate to a method, wherein the first metal gate region further includes a second depth measured from the transition location to a bottom of a third metal gate region disposed below a second vertically spaced channel structure disposed below the top vertically spaced channel structure, wherein the second depth is less than 30 nm.

In some aspects, the techniques described herein relate to a method, wherein the first metal gate region further includes a third depth measured from the transition location to a bottom of a fourth metal gate region disposed below a third vertically spaced channel structure disposed below the second vertically spaced channel structure, wherein the third depth is less than 45 nm.

In some aspects, the techniques described herein relate to a method, wherein removing remaining portions of the plurality of vertically spaced interlayer oxide regions via chemical etching operations includes removing all remaining portions of the plurality of vertically spaced interlayer oxide regions via the chemical etching operations.

In some aspects, the techniques described herein relate to a method, wherein removing remaining portions of the plurality of vertically spaced interlayer oxide regions via chemical etching operations includes removing the plurality of vertically spaced interlayer oxide regions without creating a recess between a bottom structure of the plurality of vertically spaced channel structures and a dielectric film adjacent to sidewalls of the bottom structure.

In some aspects, the techniques described herein relate to a method, including: providing a semiconductor structure including a plurality of vertically spaced channel structures and a plurality of vertically spaced sacrificial structures positioned between the plurality of vertically spaced channel structures; patterning a sacrificial gate structure over the plurality of vertically spaced channel structures, wherein the patterning provides a level of smoothness to sidewalls of the sacrificial gate structure, the patterning including: performing a main etching sequence; performing a break through etching sequence; performing a plurality of smoothing etching sequences; and performing an over etching sequence; forming gate spacers, wherein the level of smoothness of the sidewalls of the sacrificial gate structure are transferred to sidewalls of the gate spacers; forming source and drain features; removing the sacrificial gate structure; and forming a metal gate structure, wherein a level of smoothness of the sidewalls of the gate spacers are transferred to sidewalls of the metal gate structure, wherein a ratio of kinks in the metal gate structure is less than 10%, and wherein a kink is defined as a location on a vertically extending sidewall of the metal gate structure where a particular sidewall location varies in horizontal location from an average of a first sidewall location a predetermined distance above the particular sidewall location and the predetermined distance below the particular sidewall location by at least 0.5 nm.

In some aspects, the techniques described herein relate to a method, wherein the semiconductor structure after forming the metal gate structure includes a bottom angle between a sidewall of the metal gate structure and a contact surface of the metal gate structure, and the bottom angle is less than 110 degrees.

In some aspects, the techniques described herein relate to a method, wherein the semiconductor structure after forming the metal gate structure includes a width difference of less than 5 nm between a second width at a gate height of 25 nm and a first width at a gate height of 3nm.

In some aspects, the techniques described herein relate to a method, wherein the semiconductor structure after forming the metal gate structure includes a width difference of less than 3 nm between a third width at a gate height of 20 nm and a first width at a gate height of 3 nm.

In some aspects, the techniques described herein relate to a method, wherein the semiconductor structure after forming the metal gate structure includes a width difference of less than 2 nm between a fourth width at a gate height of 15 nm and a first width at a gate height of 3 nm.

In some aspects, the techniques described herein relate to a method, wherein the plurality of vertically spaced sacrificial structures includes a plurality of vertically spaced interlayer oxide regions, and further including: removing the sacrificial gate structure via dry etching operations; removing interlayer oxide above a top channel structure of the plurality of vertically spaced channel structures via dry etching operations; and removing remaining portions of the plurality of vertically spaced interlayer oxide regions via chemical etching operations.

In some aspects, the techniques described herein relate to a method, wherein removing remaining portions of the plurality of vertically spaced interlayer oxide regions via chemical etching operations includes removing all remaining portions of the plurality of vertically spaced interlayer oxide regions via the chemical etching operations.

In some aspects, the techniques described herein relate to a method, wherein removing remaining portions of the plurality of vertically spaced interlayer oxide regions via chemical etching operations includes removing the plurality of vertically spaced interlayer oxide regions without creating a recess between a bottom structure of the plurality of vertically spaced channel structures and a dielectric film adjacent to sidewalls of the bottom structure.

While at least one exemplary embodiment has been presented in the foregoing detailed description of the disclosure, it should be appreciated that a vast number of variations exist. It should also be appreciated that the exemplary embodiment or exemplary embodiments are only examples, and are not intended to limit the scope, applicability, or configuration of the disclosure in any way. Rather, the foregoing detailed description will provide those skilled in the art with a convenient road map for implementing an exemplary embodiment of the disclosure. It being understood that various changes may be made in the function and arrangement of elements described in an exemplary embodiment without departing from the scope of the disclosure as set forth in the appended claims.

What is claimed is:

1. A method, comprising:
providing a semiconductor structure comprising a plurality of vertically spaced channel structures and a plurality of vertically spaced sacrificial structures positioned between the plurality of vertically spaced channel structures;
patterning a sacrificial gate structure over the plurality of vertically spaced channel structures, wherein the patterning provides a level of smoothness to sidewalls of the sacrificial gate structure, the patterning comprising:
performing a main etching sequence;
performing a breakthrough etching sequence;
performing a plurality of smoothing etching sequences; and
performing an over etching sequence;
forming gate spacers, wherein the level of smoothness of the sidewalls of the sacrificial gate structure are transferred to sidewalls of the gate spacers;
forming source and drain features;
removing the sacrificial gate structure; and
forming a metal gate structure, wherein a level of smoothness of the sidewalls of the gate spacers are transferred to sidewalls of the metal gate structure, wherein a ratio of kinks in the metal gate structure is less than 10%, and wherein a kink is defined as a location on a vertically extending sidewall of the metal gate structure where a particular sidewall location varies in horizontal location from an average of a first sidewall location a predetermined distance above the particular sidewall location and the predetermined distance below the particular sidewall location by at least 0.5 nm.

2. The method of claim 1, wherein the semiconductor structure after forming the metal gate structure comprises a bottom angle between a sidewall of the metal gate structure and a contact surface of the metal gate structure, and the bottom angle is less than 110 degrees.

3. The method of claim 1, wherein the semiconductor structure after forming the metal gate structure comprises:
a width difference of less than 5 nm between a second width at a gate height of 25 nm and a first width at a gate height of 3 nm;
a width difference of less than 3 nm between a third width at a gate height of 20 nm and a first width at a gate height of 3 nm; and
a width difference of less than 2 nm between a fourth width at a gate height of 15 nm and a first width at a gate height of 3 nm.

4. The method of claim 1, wherein the plurality of vertically spaced sacrificial structures comprises a plurality of vertically spaced interlayer oxide regions, and further comprising:
removing the sacrificial gate structure via dry etching operations;
removing interlayer oxide above a top channel structure of the plurality of vertically spaced channel structures via dry etching operations; and
removing remaining portions of the plurality of vertically spaced interlayer oxide regions via chemical etching operations.

5. The method of claim 4, wherein removing remaining portions of the plurality of vertically spaced interlayer oxide regions via chemical etching operations comprises removing all remaining portions of the plurality of vertically spaced interlayer oxide regions via the chemical etching operations.

6. The method of claim 4, wherein removing remaining portions of the plurality of vertically spaced interlayer oxide regions via chemical etching operations comprises removing the plurality of vertically spaced interlayer oxide regions without creating a recess between a bottom structure of the plurality of vertically spaced channel structures and a dielectric film adjacent to sidewalls of the bottom structure.

7. A method, comprising:
providing a semiconductor structure comprising a plurality of vertically spaced channel structures, a plurality of vertically spaced interlayer oxide regions positioned between the plurality of vertically spaced channel structures, a sacrificial gate structure disposed above the plurality of vertically spaced channel structures, a source feature, and a drain feature;
removing the sacrificial gate structure via dry etching operations;
removing interlayer oxide above a top channel structure of the plurality of vertically spaced channel structures via dry etching operations; and
removing remaining portions of the plurality of vertically spaced interlayer oxide regions via chemical etching operations.

8. The method of claim 7, wherein removing remaining portions of the plurality of vertically spaced interlayer oxide regions via chemical etching operations comprises removing all remaining portions of the plurality of vertically spaced interlayer oxide regions via the chemical etching operations.

9. The method of claim 7, wherein removing remaining portions of the plurality of vertically spaced interlayer oxide regions via chemical etching operations comprises removing the plurality of vertically spaced interlayer oxide regions without creating a recess between a bottom structure of the plurality of vertically spaced channel structures and a dielectric film adjacent to sidewalls of the bottom structure.

10. The method of claim 7, wherein the semiconductor structure after removing remaining portions of the plurality of vertically spaced interlayer oxide regions via chemical etching operations comprises an angle between a sidewall of a bottom structure of the plurality of vertically spaced channel structures and a dielectric film disposed adjacent to the sidewall and the angle is less than 100 degrees.

11. The method of claim 7, wherein the semiconductor structure after removing remaining portions of the plurality of vertically spaced interlayer oxide regions via chemical etching operations further comprises a dielectric film disposed adjacent to a sidewall of a bottom channel structure of the plurality of vertically spaced channel structures and a first depth measured from a bottom of a top channel structure of the plurality of vertically spaced channel structures to a top of the dielectric film, wherein the first depth is approximately 45 nm.

12. The method of claim 7, wherein the semiconductor structure after removing remaining portions of the plurality of vertically spaced interlayer oxide regions via chemical etching operations further comprises a dielectric film disposed adjacent to a sidewall of a bottom channel structure of the plurality of vertically spaced channel structures and a second depth measured from a bottom of a second channel structure of the plurality of vertically spaced channel structures to a top of the dielectric film, wherein the second depth is approximately 30 nm.

13. The method of claim 7, wherein the semiconductor structure after removing remaining portions of the plurality of vertically spaced interlayer oxide regions via chemical etching operations further comprises a dielectric film disposed adjacent to a sidewall of a bottom channel structure of the plurality of vertically spaced channel structures and a third depth measured from a bottom of a third channel structure of the plurality of vertically spaced channel structures to a top of the dielectric film, wherein the third depth is approximately 15 nm.

14. A method, comprising:
providing a semiconductor structure comprising a plurality of vertically spaced channel structures, a plurality of vertically spaced interlayer oxide regions positioned between the plurality of vertically spaced channel structures, a sacrificial gate structure disposed above the plurality of vertically spaced channel structures, a source feature, and a drain feature;
removing the sacrificial gate structure via dry etching operations;
removing interlayer oxide above a top channel structure of the plurality of vertically spaced channel structures via dry etching operations;
removing remaining portions of the plurality of vertically spaced interlayer oxide regions via chemical etching operations; and
forming a metal gate structure around the plurality of vertically spaced channel structures, the metal gate structure including a first metal gate region disposed above a top vertically spaced channel structure of the plurality of vertically spaced channel structures, the first metal gate region comprising:
a vertically extending sidewall;
a horizontally extending contact area at a bottom of the first metal gate region that contacts the top vertically spaced channel structure; and
a corner angle measured at a corner between the sidewall and the contact area that is less than 100 degrees.

15. The method of claim 14, wherein:
the contact area comprises a first length that extends horizontally;
the first metal gate region further comprises a transition location on the sidewall at a location where the sidewall begins to transition toward the contact area;
the first metal gate region further comprises a second length that extends horizontally across the first metal gate region at the transition location; and
a difference between the first length and the second length is less than 15% of the second length.

16. The method of claim 15, wherein the first metal gate region further comprises a first depth measured from the transition location to a bottom of a second metal gate region disposed below the top vertically spaced channel structure, wherein the first depth is less than 15 nm.

17. The method of claim 16, wherein the first metal gate region further comprises a second depth measured from the transition location to a bottom of a third metal gate region disposed below a second vertically spaced channel structure disposed below the top vertically spaced channel structure, wherein the second depth is less than 30 nm.

18. The method of claim 17, wherein the first metal gate region further comprises a third depth measured from the transition location to a bottom of a fourth metal gate region disposed below a third vertically spaced channel structure disposed below the second vertically spaced channel structure, wherein the third depth is less than 45 nm.

19. The method of claim 14, wherein removing remaining portions of the plurality of vertically spaced interlayer oxide regions via chemical etching operations comprises removing all remaining portions of the plurality of vertically spaced interlayer oxide regions via the chemical etching operations.

20. The method of claim 14, wherein removing remaining portions of the plurality of vertically spaced interlayer oxide regions via chemical etching operations comprises removing the plurality of vertically spaced interlayer oxide regions without creating a recess between a bottom structure of the plurality of vertically spaced channel structures and a dielectric film adjacent to sidewalls of the bottom structure.
